(19) United States
(12) Patent Application Publication
(10) Pub. No.: US 2026/0147424 A1
(43) Pub. Date: May 28, 2026

(54) DISPLAY APPARATUS

(71) Applicant: LG Display Co., Ltd., Seoul (KR)

(72) Inventors: HoonBae KIM, Paju-si (KR); NamYong GONG, Paju-si (KR); SungChul KIM, Paju-si (KR); SunYeop KIM, Paju-si (KR); Sung-Jin KANG, Paju-si (KR); Jongsung KIM, Paju-si (KR)

(73) Assignee: LG Display Co., Ltd., Seoul (KR)

(21) Appl. No.: 19/360,831

(22) Filed: Oct. 16, 2025

(30) Foreign Application Priority Data
Nov. 26, 2024 (KR) 10-2024-0170704

(51) Int. Cl. G06F 3/041; G06F 3/044; H01L 25/16; H10H 29/37; H10H 29/49; H10H 29/855

(52) U.S. Cl. CPC G06F 3/04164; G06F 3/0412; G06F 3/0446; G06F 3/0448; H10H 29/37; H10H 29/49; H10H 29/8552; H10W 90/00; G06F 2203/04111

(57) ABSTRACT

A display apparatus is capable of improving touch sensitivity at an edge portion of a screen. The display apparatus can include a display panel having a plurality of pixel driving circuits, a touch panel configured on the display panel, and a touch auxiliary line configured at the display panel or the touch panel. The touch panel comprises first to n^{th} touch driving lines, and first to m^{th} touch sensing lines configured to form a mutual capacitance with adjacent touch driving lines of the first to n^{th} touch driving lines, where n and m are each a natural number equal to or greater than 4. The touch auxiliary line is spaced apart from an end of each of the first to n^{th} touch driving lines and is configured to form the mutual capacitance with at least some of the first to m^{th} touch sensing lines.

### CROSS-REFERENCE TO RELATED APPLICATION

This application claims the benefit of and priority to Korean Patent Application No. 10-2024-0170704, filed in the Republic of Korea on Nov. 26, 2024, the entirety of which is hereby incorporated by reference for all purposes as if fully set forth herein.

### BACKGROUND

### Technical Field

The present disclosure relates to a display apparatus/device.

### Description of the Related Art

The display apparatus is applied to various electronic apparatuses such as televisions (TVs), mobile phones, laptops, and tablets.

The display apparatus includes an organic light emitting display apparatus that emit light by themselves and a liquid crystal display apparatus that require a separate light source.

Recently, a display apparatus including a light emitting device has attracted attention as a next-generation display apparatus. The light emitting device is made of an inorganic material, not an organic material. Accordingly, compared to the liquid crystal display apparatus or the organic light emitting display apparatus, the display apparatus including the light emitting device has a faster lighting speed and excellent luminous efficiency, and displays an image having high luminance.

Electronic devices using a display apparatus as a display screen provide a user interface of a touch screen type, for convenience of a user input. Display apparatuses capable of touch interface processing are advancing to provide more various functions. For example, display apparatuses including a touch panel which is capable of touch sensing based on a touch pen (or a stylus pen) as well as finger touch sensing based on a finger, are being widely used.

### SUMMARY OF THE DISCLOSURE

The inventors of the present disclosure recognized that the touch sensitivity (or touch performance) at an edge portion of a screen can be deteriorated in the display apparatus including a touch electrode layer of a mutual-capacitance type, and has performed extensive research and

experiments for inventing display devices which are capable of improving the touch sensitivity at the edge portion of the screen. Based on the extensive research and experiments, the inventors of the present disclosure have invented a new and improved display apparatus capable of improving the touch sensitivity at the edge portion of the screen.

An aspect of the present disclosure is directed to providing a display apparatus capable of improving touch sensitivity at an edge portion of a screen.

An aspect of the present disclosure is directed to providing a display apparatus capable of simplifying the structure and low-power driving.

Another aspects of the present disclosure is to provide an improved display apparatus/device, which can address or overcome limitations and disadvantages associated with the related art display apparatus/device.

Additional features, advantages, and aspects of the present disclosure are set forth in part in the present disclosure and will also be apparent from the present disclosure or can be learned by practice of the inventive concepts provided herein. Other features, advantages, and aspects of the present disclosure can be realized and attained by the descriptions provided in the present disclosure, or derivable therefrom, and claims hereof as well as the appended drawings.

To achieve these and other advantages and aspects of the present disclosure, as embodied and broadly described herein, in one or more aspects, a display apparatus according to one or more embodiments of the present disclosure comprises a display panel including a plurality of pixel driving circuits, a touch panel configured on the display panel, and a touch auxiliary line configured at the display panel or the touch panel. The touch panel comprises first to n^{th} (n is a natural number equal to or greater than 4) touch driving lines, and first to m^{th} (m is a natural number equal to or greater than 4) touch sensing lines configured to form a mutual capacitance with adjacent touch driving lines of the first to n^{th} touch driving lines. The touch auxiliary line is spaced apart from an end of each of the first to n^{th} touch driving lines and is configured to form the mutual capacitance with at least some of the first to m^{th} touch sensing lines.

Details of other example embodiments of the present disclosure will be included in the detailed description of the disclosure and the accompanying drawings.

In the display apparatus according to one or more embodiments of the present disclosure, touch sensitivity at an edge portion of a screen can be improved.

In the display apparatus according to one or more embodiments of the present disclosure, power consumption can be reduced, and thus, improved ESG (environmental, social, and governance) can be implemented.

According to one or more embodiments of the present disclosure, instead of directly forming pixel circuits for driving the light emitting devices configured in each of the plurality of sub-pixels on a substrate, the structure of the display apparatus can be simplified, and high-efficiency driving and low-power driving can be achieved by mounting a pixel driving circuit (or pixel driving integrated circuit), in which the pixel circuits are integrated, on the substrate.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are examples and explanatory and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure.

FIG. 1 is an exploded perspective view illustrating a display apparatus according to an embodiment of the present disclosure.

FIG. 2 is a plan view of a display apparatus according to an embodiment of the present disclosure.

FIG. 3 is an enlarged view of the display apparatus according to an embodiment of the present disclosure.

FIG. 4 is a diagram illustrating a circuit structure according to an embodiment of the present disclosure.

FIGS. 5 to 7 are plan views of a display apparatus according to an embodiment of the present disclosure.

FIG. 8 is a cross-sectional view taken along line I-I′ illustrated in FIG. 2.

FIG. 9 is a cross-sectional view of a first light emitting device according to an embodiment of the present disclosure.

FIG. 10 is a diagram illustrating driving timing of a display panel and a touch panel according to an embodiment of the present disclosure.

FIG. 11 is a plan view illustrating an electrode structure of a touch panel according to an embodiment of the present disclosure.

FIG. 12 is an enlarged view of ‘A’ illustrated in FIG. 11.

FIG. 13 is a cross-sectional view taken along line II-II′ illustrated in FIG. 12.

FIG. 14 is a diagram illustrating an output signal of a touch driving circuit according to an embodiment of the present disclosure.

FIG. 15 is a diagram illustrating capacitance formed on an edge sensing line of the touch panel illustrated in FIGS. 11 and 12.

FIG. 16 is a diagram illustrating capacitance formed on an intermediate sensing line of the touch panel illustrated in FIGS. 11 and 12.

FIG. 17 is a diagram illustrating an output signal of a touch driving circuit according to another embodiment of the present disclosure.

FIG. 18 is a diagram illustrating a touch panel of a display apparatus according to another embodiment of the present disclosure.

FIG. 19 is a diagram illustrating a second electrode and a touch panel in a display apparatus according to another embodiment of the present disclosure.

FIG. 20 is an enlarged view of ‘B’ illustrated in FIG. 19.

FIG. 21 is a cross-sectional view taken along line III-III′ illustrated in FIG. 20.

FIG. 22 is a diagram illustrating a touch panel of a display apparatus according to another embodiment of the present disclosure.

FIGS. 23 to 26 are diagrams illustrating different examples of an apparatus to which a display apparatus according to embodiments of the present disclosure is applied.

Throughout the drawings and the detailed description, unless otherwise described, the same drawing reference numerals should be understood to refer to the same elements, features, and structures. The sizes, lengths, and thicknesses of layers, regions and elements, and depiction of thereof can be exaggerated for clarity, illustration, and convenience.

### DETAILED DESCRIPTION OF THE EMBODIMENTS

Advantages and features of the present disclosure, and implementation methods thereof, are clarified through the aspects described with reference to the accompanying drawings. The present disclosure can, however, be embodied in different forms and should not be construed as limited to the example aspects set forth herein. Rather, these example aspects are examples and are provided so that this disclosure can be thorough and complete to assist those skilled in the art to understand the inventive concepts without limiting the protected scope of the present disclosure.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. In a situation where terms such as “comprise,” “have,” and “include” described in the present disclosure are used, another part can be added unless “only” is used. The terms of a singular form can include plural forms unless referred to the contrary.

In construing an element, the element is construed as including an error range although there is no explicit description.

In describing a position relationship, for example, when a position relation between two parts is described as “on”, “over”, “under”, “next”, and “adjacent to” or the like, one or more other parts can be located between the two parts unless a more limiting term, such as “immediate(ly)”, “direct(ly)”, or “close(ly)” is used.

In describing a temporal relationship, when the temporal order is described as, for example, “after”, “subsequent”, “next”, “before”, or the like, a case that is not consecutive or not sequential can be included and thus one or more other events can occur therebetween, unless a more limiting term, such as “immediate(ly)” or “direct(ly)” is used.

It is understood that, although the terms such as “first,” “second,” or the like can be used herein to describe various elements, these elements should not be limited by these terms, for example, to any particular order, sequence, precedence, or number of elements. These terms are used only to distinguish one element from another. Therefore, the first element described below

can be understood as the second element within the scope of the technical idea of the present disclosure.

In describing elements of the present disclosure, the terms such as “first”, “second”, “A”, “B”, “(a)”, “(b)”, or the like can be used. These terms are intended to identify the corresponding element from the other element, and these are not used to define the essence, basis, order, or number of the elements.

For the expression that an element is “connected”, “coupled”, or “attach” to another element, the element may not only be directly connected, coupled, or contacted to another element, but also be indirectly connected, coupled or attached to another element with one or more intervening elements interposed between the elements, unless otherwise specified.

For the expression that an element is “overlaps” with another element, the element can not only directly contact, overlap, or the like with another element, but also indirectly overlap with another element with one or more intervening elements disposed or interposed between the elements, unless otherwise specified.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Further, terms such as “first direction”, “second direction”, “third direction”, “X-axis direction”, “Y-axis direction”, and “Z-axis direction” should not be construed by a geometric relation only of a mutual vertical relation and can have broader directionality within the range that elements of the present disclosure can act functionally. In addition, the term “can” fully encompasses all the meanings and coverages of the term “can” and vice versa.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

Hereinafter, example embodiments of a display apparatus according to the present disclosure will be described in detail with reference to the accompanying drawings. All the

components of each display apparatus/device according to all embodiments of the present disclosure are operatively coupled and configured. For convenience of description, a scale of each of elements illustrated in the accompanying drawings differs from a real scale, and thus, is not limited to a scale illustrated in the drawings.

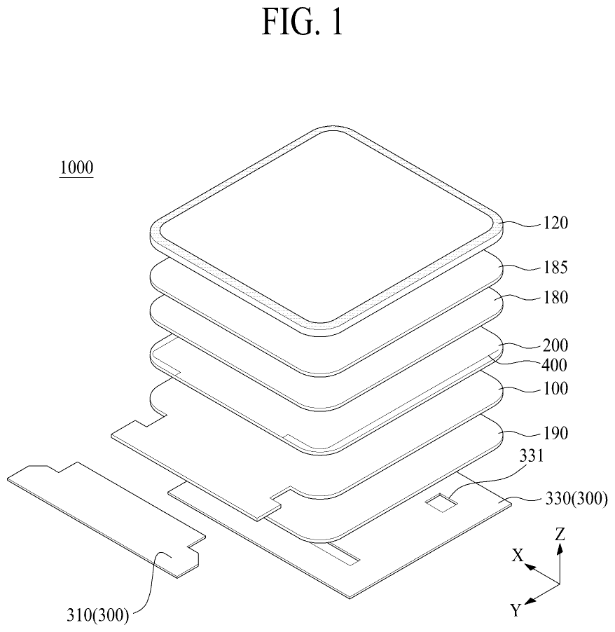

FIG. 1 is an exploded perspective view illustrating a display apparatus according to an embodiment of the present disclosure.

Referring to FIG. 1, a display apparatus 1000 according to an embodiment of the present disclosure can include a display panel 100, a touch panel 200, and a touch auxiliary line 400.

The display panel 100 can be configured to implement information, video, and/or images provided to a user on a screen. For example, the display panel 100 can be a light emitting display panel including a plurality of pixels having a light emitting device.

The touch panel 200 can be disposed (or configured) to vertically overlap the display panel 100. The touch panel 200 can be configured to sense a user touch on the display panel 100. For example, the touch panel 200 can be configured to sense the user touch via a touch pen or a finger.

The touch panel 200 according to one embodiment of the present disclosure can include a touch electrode layer in which first to nth (where n is a natural number of 4 or more) touch driving lines (or a plurality of first touch lines) and first to mth (where m is a natural number of 4 or more) touch sensing lines (or a plurality of second touch lines) are configured to intersect each other. The touch sensing lines can be configured to form a mutual capacitance with adjacent touch driving lines of the first to nth touch driving lines. For example, the touch panel 200 can be configured to sense a change in mutual capacitance between the touch driving lines and the touch sensing lines based on the user touch. For example, the touch panel 200 (or the touch electrode layer) can include an electrode structure corresponding to a mutual capacitance type.

The touch auxiliary line 400 can be configured to improve touch sensitivity (or touch performance) at an edge portion of the screen. For example, the touch auxiliary line 400 can be disposed (or configured) at the display panel 100 or the touch panel 200.

The touch auxiliary line 400 according to one embodiment of the present disclosure can be spaced apart from ends of each of the first to n^{th} touch driving lines, and can be disposed (or configured) to form mutual capacitance with at least some of the first to m^{th} touch sensing lines. For example, the touch auxiliary line 400 can be disposed (or configured) to increase or add capacitance of the first and m^{th} touch sensing lines disposed (or configured) at the edge portion of

the screen among the first to m^{th} touch sensing lines. For example, the touch auxiliary line 400 can be disposed (or configured) to increase the total capacitance of each of the first and m^{th} touch sensing lines. Therefore, as the capacitance between each of the first and m^{th} touch sensing lines disposed at the edge portion of the screen and the touch auxiliary line 400 increases (or is reinforced), touch sensitivity (or touch performance) at the edge portion of the screen can be improved.

The display apparatus 1000 according to an embodiment of the present disclosure can further include a cover member 120, a supporting substrate 190, and a driving circuit part 300.

The cover member 120 can be disposed over the display panel 100. The cover member 120 can be a member to protect the display panel 100. The cover member 120 can be made of a transparent material. For example, the cover member 120 can be a cover window or cover glass.

The supporting substrate 190 can be disposed at a rear surface of the display panel 100. The supporting substrate 190 can be configured to reinforce the rigidity of the display panel 100. For example, the supporting substrate 190 can be made of a plastic or metal material. The supporting substrate 190 can be a back plate.

A portion of the display panel 100 can be bent to surround side surfaces (or lateral surfaces) of the supporting substrate 190 and can be disposed at a rear surface of the supporting substrate 190.

The driving circuit part (or the display driving circuit part) 300 can be configured to be electrically connected to the display panel 100. The driving circuit part 300 can be configured to generate signals required to display (or implement) an image on the display panel 100 and supply the signals to the display panel 100. The driving circuit part 300 can include a flexible circuit board 310 and a printed circuit board 330.

The flexible circuit board 310 and the printed circuit board 330 can be disposed at a lower portion of the display panel 100. The flexible circuit board 310 and the printed circuit board 330 can be disposed at least one side edge portion of the display panel 100. One side of the flexible circuit board 310 can be attached to the display panel 100, and the other side of the flexible circuit board 310 can be attached to the printed circuit board 330. The flexible circuit board 310 can be a flexible film.

The flexible circuit board 310 and the printed circuit board 330 can be disposed at the rear surface of the supporting substrate 190. The supporting substrate 190 can be disposed between the display panel 100 and the printed circuit board 330.

The printed circuit board 330 can include at least one hole 331, but is not limited thereto. An internal component that sense ambient light or temperature, or the like, which can be provided to a plurality of sensors, can be disposed in a region corresponding to the at least one hole 331. For example, the internal component can include an ambient light sensor or a temperature sensor, or the like, but is not limited thereto. For example, the at least one hole 331 can be a transmission hole or the like, but is not limited thereto.

The driving circuit part 300 can be electrically connected to the touch panel 200. The driving circuit part 300 can be electrically connected to the first to n^{th} touch driving lines, the first to m^{th} touch sensing lines, and the touch auxiliary line 400. The driving circuit part 300 can be configured to supply a touch driving signal to each of the first to n^{th} touch driving lines, and to supply an auxiliary driving signal, synchronized with the touch driving signal, to the touch auxiliary line 400. The driving circuit part 300 can also be configured to sense a change in capacitance of each of the first to m^{th} touch sensing lines, generate touch coordinate data corresponding to a touch position of a user, and provide the touch coordinate data to a host control part.

The display apparatus 1000 according to an embodiment of the present disclosure can further include a polarizing layer 180 and an adhesive layer 185.

The polarizing layer 180 can be disposed over the display panel 100. The polarizing layer 180 can be disposed (or interposed) between the display panel 100 and the cover member 120. For example, the polarizing layer 180 can be disposed over the touch panel 200. The polarizing layer 180 can be disposed (or interposed) between the touch panel 200 and the cover member 120. The polarizing layer 180 can be configured to prevent or reduce light generated from an external light source from entering an interior of the display panel 100 and affecting light emitting devices or the like.

The adhesive layer 185 can attach the cover member 120 to the display panel 100. The adhesive layer 185 can be disposed (or interposed) between the polarizing layer 180 and the cover member 120, and can attach the cover member 120 to the polarizing layer 180. The adhesive layer 185 can include an optically cleared adhesive, an optically cleared resin, or a pressure sensitive adhesive, or the like.

The touch panel 200 according to another embodiment of the present disclosure can be

interposed or disposed between the display panel 100 and the cover member 120. For example, the touch panel 200 can be interposed or disposed between the cover member 120 and the polarizing layer 180. The touch panel 200 can be connected or attached to a rear surface of the cover member 120 by a transparent adhesive member.

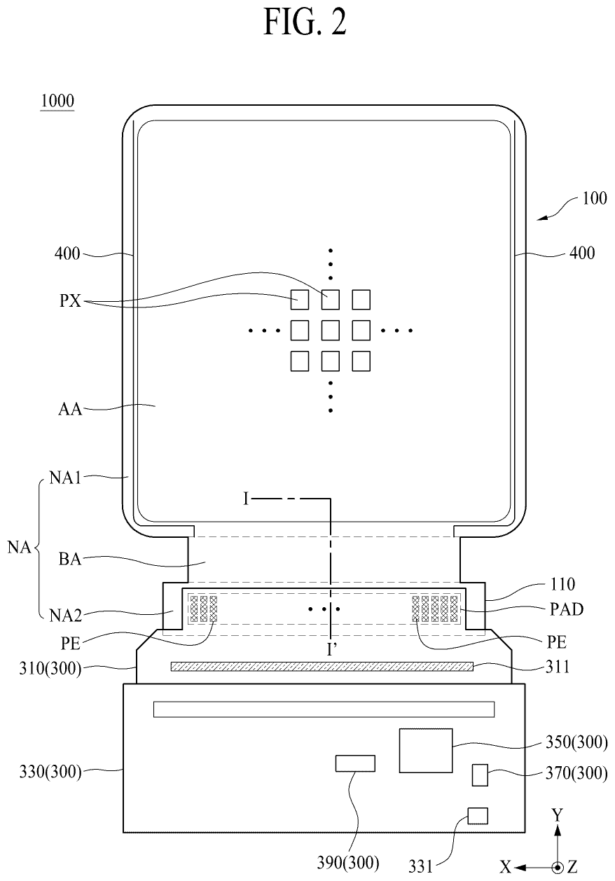

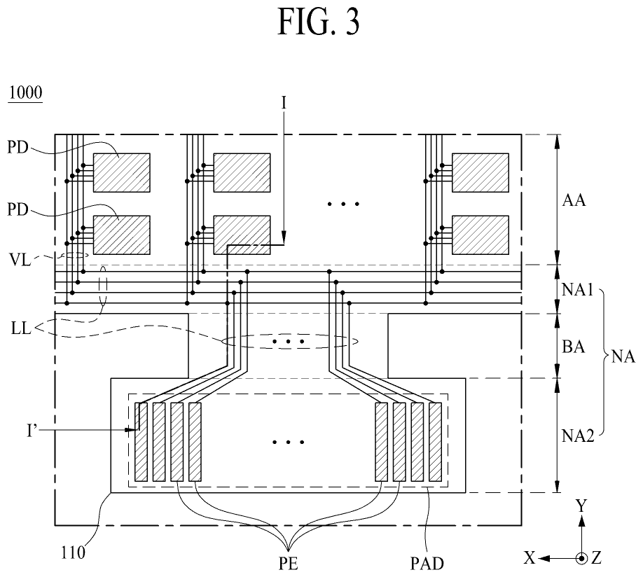

FIG. 2 is a plan view of a display apparatus according to an embodiment of the present disclosure, and FIG. 3 is an enlarged view of the display apparatus according to an embodiment of the present disclosure.

Referring to FIGS. 2 and 3, the display apparatus 1000 can include the display panel 100, a flexible circuit board 310, and a printed circuit board 330.

The display panel 100 can include a substrate 110. The substrate 110 can be a member configured to support the other components of the display apparatus 1000. The substrate 110 can be made of an insulating material. For example, the substrate 110 can be made of glass or resin, or the like. In addition, the substrate 110 can be made of a material having flexibility. For example, the substrate 110 can be made of a plastic material having flexibility, such as polyimide, or the like, but is not limited thereto.

The display panel 100 can include a display area AA (or active area) and a non-display area NA (or non-active area). For example, the substrate 110 can include a display area AA and a non-display area NA. The display area AA and the non-display area NA are not limited to the substrate 110 but can be described throughout the display apparatus 1000.

The display area AA can be an area (or a screen) where an image is displayed. The display area AA can include a plurality of pixels PX. Each of the plurality of pixels PX can be composed of a plurality of sub-pixels. For example, each of the plurality of pixels PX can include a plurality of sub-pixels. Each of the plurality of sub-pixels can include a plurality of light emitting devices. The plurality of light emitting devices can be configured differently depending on the type of the display apparatus 1000. For example, when the display apparatus 1000 is an inorganic light emitting display apparatus, the light emitting device can be an LED (light emitting diode), a micro LED (micro light emitting diode), or a mini LED (mini light emitting diode), but is not limited thereto.

The display area AA can be configured in various shapes according to a design of the display apparatus 1000. For example, the display area AA can be configured in a rectangular shape with four corners formed in a round shape, but is not limited thereto. For another example, the display area AA can be configured in a rectangular shape with four corners formed in right-angled shape or a circular shape, or the like, but is not limited thereto.

Referring to FIG. 3, a plurality of pixel driving circuits PD can be disposed at the display area AA. The plurality of pixel driving circuits PD can be circuits for driving the light emitting devices of the plurality of sub-pixels. Each of the plurality of pixel driving circuits PD includes a plurality of transistors including a driving transistor and a storage capacitor, or the like, and can control light emitting operations of the plurality of light emitting devices by supplying a control signal, power, and a driving current to the light emitting devices of the plurality of sub-pixels. For example, each of the plurality of pixel driving circuits PD can be electrically connected to a power wiring disposed (or configured) at the display area AA, and a signal wiring for controlling light emitting on/off and/or light emitting time of the light emitting devices. For example, each of the plurality of pixel driving circuits PD can be a microchip, a pixel driving chip, or a chipset, and can be a semiconductor packaging device having one fine size including a plurality of transistors and a storage capacitor. For example, each of the plurality of pixel driving circuits PD can be a driving driver manufactured using a MOSFET (Metal-oxide-semiconductor field effect transistor) manufacturing process on a semiconductor substrate, but is not limited thereto. The driving driver includes the plurality of pixel driving circuits PD and can drive the plurality of sub-pixels.

The non-display area NA can be an area surrounding the display area AA. The non-display area NA can be an area where an image is not displayed. The non-display area NA can include various wirings and driving circuits or the like for driving the plurality of pixels PX disposed (or configured) at the display area AA. For example, the various wirings and the driving circuits can be mounted at the non-display area NA, and a pad portion PAD which is connected to an integrated circuit and a printed circuit board or the like can be disposed at the non-display area NA, but is not limited thereto.

According to an embodiment of the present disclosure, the driving circuit can include a driving integrated circuit (or display driving circuit) 311. For example, the driving circuit can be a data driving circuit and/or a gate driving circuit, but is not limited thereto. Wires to which a control signal for controlling the driving circuit is supplied can be disposed at the non-display area NA. For example, the control signal can include various timing signals including a clock signal, an input data enable signal, and synchronization signals, but is not limited thereto. The control signal can be received through the pad portion PAD. For example, link lines LL for transmitting the signals can be disposed at the non-display area NA. For example, the pad portion PAD can be electrically connected to the driving circuit of the driving circuit part 300.

According to an embodiment of the present disclosure, the non-display area NA can include a first non-display area NA1, a bending area BA, and a second non-display area NA2. For example, the first non-display area NA1 can be an area surrounding at least a portion of the display area AA. The bending area BA can be an area extending from at least one of a plurality of sides of the first non-display area NA1 and can be a bendable area. The second non-display area NA2 can be an area extending from the bending area BA and can have the pad portion PAD disposed therein. For example, the bending area BA can be in a bent state, and the remaining area of the substrate 110 excluding the bending area BA can be in a flat state. In this case, as the bending area BA is bent, the second non-display area NA2 can be located on a rear surface of the display area AA, but is not limited thereto.

According to an embodiment of the present disclosure, a plurality of link lines LL can be disposed at the non-display area NA. The plurality of link lines LL can be lines that transmit various signals from one or more flexible circuit boards (or flexible films) 310 and the printed circuit boards 330 to the display area AA. The plurality of link lines LL can extend from a plurality of pad electrodes PE of the second non-display area NA2 toward the bending area BA and the first non-display area NA1, and can be electrically connected to a plurality of driving lines VL of the display area AA. The plurality of pixel driving circuits PD can be driven by receiving signals from the one or more flexible circuit boards (or flexible films) 310 and the printed circuit boards 330 through the driving lines VL of the display area AA and the link lines LL of the non-display area NA.

According to an embodiment of the present disclosure, the plurality of driving lines VL, together with the plurality of link lines LL, can be lines for transmitting signals output from the flexible circuit board 310 and the printed circuit board 330 to the plurality of pixel driving circuits PD. The plurality of driving lines VL can be disposed at the display area AA and can be electrically connected to each of the plurality of pixel driving circuits PD. The plurality of driving lines VL can extend from the display area AA toward the non-display area NA and can be electrically connected to the plurality of link lines LL. Therefore, signals output from the flexible circuit board 310 and the printed circuit board 330 can be transmitted to each of the plurality of pixel driving circuits PD through the plurality of link lines LL and the plurality of driving lines VL.

According to an embodiment of the present disclosure, as the bending area BA is bent, a portion of the plurality of link lines LL can be bent together. Stress is concentrated on the portion of the bent link lines LL, and thus cracks can occur in the link lines LL. Accordingly, the plurality of link lines LL can be composed of a conductive material having excellent flexibility in order to reduce cracks when the bending area BA is bent. For example, the plurality of link lines LL can be composed of a conductive material having excellent flexibility, such as gold (Au), silver (Ag), aluminum (Al), or the like, but is not limited thereto. In addition, the plurality of link lines LL can also be configured as one of various conductive materials used in the display area AA. The plurality of link lines LL can be composed of a multilayer structure including various conductive materials. For example, the plurality of link lines LL can be composed of a triple layer structure of titanium (Ti)/aluminum (Al)/titanium (Ti), but is not limited thereto.

The plurality of link lines LL can be configured in various shapes to reduce stress. At least a portion of the plurality of link lines LL disposed on the bending area BA can extend in the same direction as an extension direction of the bending area BA, or can extend in a direction different from the extension direction of the bending area BA to reduce stress. For example, when the bending area BA extends in one direction from the first non-display area NA1 toward the second non-display area NA2, the at least the portion of the link lines LL disposed on the bending area BA can extend in a direction inclined with respect to the one direction. As another example, the at least the portion of the plurality of link lines LL can be configured in patterns of various shapes. For example, the at least the portion of the plurality of link lines LL disposed on the bending area BA can have a pattern in which conductive patterns having at least one shape of a diamond shape, a rhombus shape, a trapezoidal wave shape, a triangular wave shape, a sawtooth wave shape, a sine wave shape, a circular shape, and an omega (Ω) shape are repeatedly disposed, but is not limited thereto. Accordingly, in order to minimize stress concentrated on the plurality of link lines LL and cracks resulting therefrom, the shapes of the plurality of link lines LL can be formed in various shapes including the above-described shapes, but is not limited thereto.

According to an embodiment of the present disclosure, a width of the second non-display area NA2 in which the plurality of pad electrodes PE are disposed can be wider than a width of the bending area BA in which only the plurality of link lines LL are disposed. In addition, a width of the display area AA in which the plurality of sub-pixels are disposed can be wider than the width of the bending area BA in which only the plurality of link lines LL are disposed. Although the width

of the bending area BA is illustrated as being narrower than a width of other area of the substrate 110 in the drawings, a shape of the substrate 110 including the bending area BA can be an example, but is not limited thereto.

The pad portion PAD including the plurality of pad electrodes PE can be disposed at the second non-display area NA2. The one or more flexible circuit boards 310 can be attached or bonded to the pad portion PAD. The plurality of pad electrodes PE of the pad portion PAD can be electrically connected to the one or more flexible circuit boards 310 and can transmit various signals (or power) received from the printed circuit board 330 and the flexible circuit board 310 to the plurality of pixel driving circuits PD of the display area AA.

The flexible circuit board 310 can be a film in which various components are disposed on a base film having flexibility. For example, the driving integrated circuit 311 including one or more of a gate driver integrated circuit and a data driver integrated circuit can be disposed at the flexible circuit board 310, but is not limited thereto. The driving integrated circuit 311 can be a component that processes data and a driving signal for displaying an image. The driving integrated circuit 311 can be disposed in a manner such as a chip on glass (COG), a chip on film (COF), or a tape carrier package (TCP) based on a mounting method, but is not limited thereto. The flexible circuit board 310 can be attached or bonded on the plurality of pad electrodes PE through a conductive adhesive layer, but is not limited thereto.

The printed circuit board 330 is electrically connected to one or more flexible circuit boards 310 and can be a component that supplies signals to the driving integrated circuit 311. The printed circuit board 330 can be disposed on one side of the flexible circuit board 310 and can be electrically connected to the flexible circuit board 310. Circuit components such as a memory or various passive circuit elements or the like for supplying various signals to the driving integrated circuit 311 can be additionally disposed at the printed circuit board 330.

The driving circuit part 300 according to an embodiment of the present disclosure can further include a timing controller 350 and a power management integrated circuit 370.

The timing controller 350 can be mounted on a printed circuit board 330. The timing controller 350 receives image data and a timing synchronization signal provided from a host control part, converts the image data into pixel data and provides the pixel data to the driving integrated circuit 311, and controls the driving timing of each of the driving integrated circuit 311 and the plurality of pixel driving circuits PD based on the timing synchronization signal. For example, the timing controller 350 can be embedded in the driving integrated circuit 311 or implemented (or configured) inside the driving integrated circuit 311.

The power management integrated circuit (or power driving part or power generating part) 370 can be configured to generate and output various powers required for driving the display apparatus 1000. For example, the power management integrated circuit 370 can be configured to generate and output a power voltage, a reference voltage, a cathode-on voltage, a cathode-off voltage, or the like according to the control of the timing controller 350 based on the input power. For example, the driving voltage can be a voltage for driving a driving circuit or an integrated circuit. The reference voltage can be a voltage for controlling (or determining) brightness (or luminance) of an image displayed in the display area AA or light emitted from the light emitting device. The cathode-on voltage can be a voltage for turning on (or emitting) the light emitting device. The cathode-off voltage can be a voltage for turning off the light emitting device. For example, the cathode-on voltage can be a first common voltage or a first low-potential power voltage, and the cathode-off voltage can be a second common voltage or a second low-potential power voltage, but is not limited thereto.

The driving circuit part 300 according to an embodiment of the present disclosure can further include a touch driving circuit (or a touch integrated circuit) 390.

The touch driving circuit 390 can be configured to be electrically connected to the first to n^{th} touch driving lines, the first to m^{th} touch sensing lines, and the touch auxiliary line 400 in the touch panel 200. The touch driving circuit 390 can supply a touch driving signal to the first to n^{th} touch driving lines and simultaneously supply an auxiliary driving signal to the touch auxiliary line 400 in response to a touch synchronization signal supplied from the timing controller 350, generate touch raw data corresponding to changes in capacitance of each of the first to m^{th} touch sensing lines, and provide the generated touch raw data to the timing controller 350 or the host control part, but is not limited thereto. For example, the touch driving circuit 390 can be configured to generate touch coordinate data based on the touch raw data and provide the touch coordinate data to the host control part. For example, the touch driving circuit 390 can be integrated or built into the driving integrated circuit 311.

The timing controller 350 can be configured to control voltages output from the power management integrated circuit 370 based on user touch information provided from the touch driving circuit 390 or the host control part. For example, when a user adjusts a screen brightness (or luminance) of the display apparatus 1000 through the touch panel 200 or button operation, the timing controller 350 can be configured to provide reference voltage data and the cathode-off voltage data (or second common voltage data) to the power management integrated circuit 370 based on screen brightness data corresponding to the screen brightness according to the user operation (or setting). The power management integrated circuit 370 can be configured to generate and output the reference voltage and the cathode-off voltage based on each of the reference voltage data and the cathode-off voltage data provided from the timing controller 350.

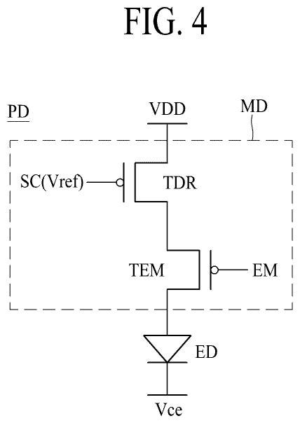

FIG. 4 is a diagram illustrating a circuit structure according to an embodiment of the present disclosure. Particularly, FIG. 4 is a diagram illustrating one micro-driver included in each of the plurality of pixel driving circuits illustrated in FIG. 3.

Referring to FIG. 4, one light emitting device ED is connected to one micro-driver MD as an example, but is not limited thereto. For example, 8 light emitting devices ED can be connected to the one micro-driver MD. For example, 8 light emitting devices ED in different lines (or horizontal lines or row lines) can be connected to the one micro-driver MD. In another example, 16 light emitting devices ED can be connected to the one micro-driver MD, or 32 light emitting devices ED or 64 light emitting devices ED can be simultaneously (or commonly) connected to the one micro-driver MD. For example, the micro-driver MD can be a sub-driver MD. For example, the light emitting device ED can be a micro light emitting device, a micro light emitting diode, or a micro light emitting diode chip. For example, the light emitting device ED can have a scale of 1 μm to 100 μm, but is not limited thereto.

The one micro-driver MD can be configured to apply a driving current (or data current) based on a scan signal (or reference voltage) and an emission signal to the light emitting device ED. The one micro-driver MD according to an embodiment of the present disclosure can include a driving transistor TDR and a light emitting transistor TEM, but is not limited thereto.

According to an embodiment of the present disclosure, a high-potential power voltage VDD can be applied to a first electrode of the driving transistor TDR, a first electrode of the light emitting transistor TEM can be connected to a second electrode of the driving transistor TDR, and a scan signal SC can be applied to a gate electrode of the driving transistor TDR. The scan signal SC applied to the gate electrode of the driving transistor TDR is a direct current DC power, and a fixed reference voltage Vref can be applied for each frame, but is not limited thereto. For example, the reference voltage Vref can be changed for one or more frames. For example, the reference voltage Vref can be adjusted (or varied) based on the screen brightness according to the user operation (or setting).

According to an embodiment of the present disclosure, the second electrode of the driving transistor TDR can be connected to the first electrode of the light emitting transistor TEM, the light emitting device ED can be connected to a second electrode of the light emitting transistor TEM, and the emission signal EM can be applied to a gate electrode of the light emitting transistor TEM. The emission signal EM applied to the gate electrode of the light emitting transistor TEM can be a pulse width modulation signal that varies for each frame, but is not limited thereto. For example, the emission signal EM can include a duty-on period that turns on the light emitting transistor TEM and a duty-off period that turns off the light emitting transistor TEM. For example, the duty-on period of the emission signal EM can be set (or adjusted) by a grayscale corresponding to pixel data.

A first electrode of the light emitting device ED can be connected to the second electrode of the light emitting transistor TEM, and a second electrode of the light emitting device ED can be connected to a low-potential power line. For example, the first electrode of the light emitting device ED can be an anode electrode or an anode terminal, and the second electrode of the light emitting device ED can be a cathode electrode or a cathode terminal, but is not limited thereto. For example, the voltage applied from the light emitting transistor TEM to the first electrode of the light emitting device ED can be an anode voltage. For example, the voltage applied to the low-potential power line can be a cathode voltage Vce. For example, the voltage applied to the low-potential power line can be a cathode-on voltage or a cathode-off voltage. For example, one or more of the cathode-on voltage and the cathode-off voltage can be varied (or adjusted). For example, one or more of the cathode-on voltage and the cathode-off voltage can be varied (or adjusted) according to the screen brightness according to user operation (or setting). For example, one or more of the cathode-on voltage and the cathode-off voltage can be varied (or adjusted) according to the reference voltage Vref.

Each of the driving transistor TDR and the light emitting transistor TEM can be an n-type transistor or a p-type transistor.

In the micro-driver MD, the driving transistor TDR can be turned on by the scan signal SC applied from the pixel driving circuit PD, and the light emitting transistor TEM can be turned on by the emission signal EM applied from the pixel driving circuit PD. Accordingly, the driving current

is applied to the light emitting device ED through the driving transistor TDR and the light emitting transistor TEM by the high-potential power voltage VDD applied to the first electrode of the driving transistor TDR, and thus, the light emitting device ED can emit light. For example, the light emitting device ED can emit light while the cathode-on voltage is applied to the low-potential power line, and may not emit light while the cathode-off voltage is applied to the low-potential power line.

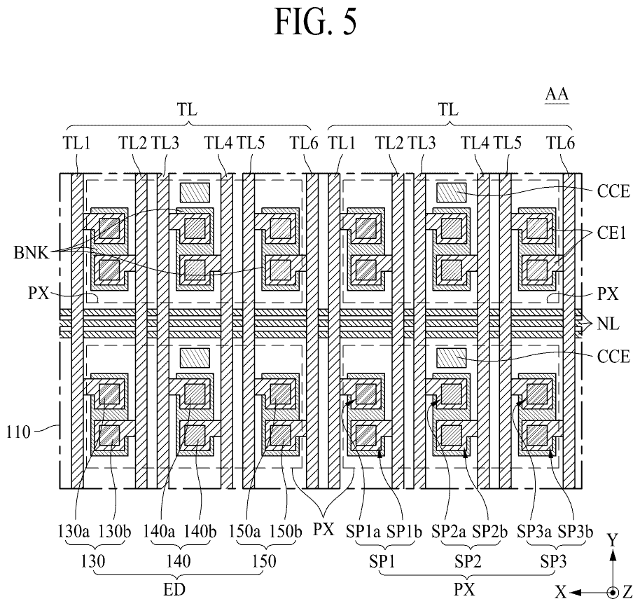

FIGS. 5 to 7 are plan views of a display apparatus according to an embodiment of the present disclosure. For example, FIG. 5 is an enlarged view of a display area including a plurality of pixels. For example, FIG. 6 is an enlarged view of a display area including one pixel. For example, FIG. 7 is an enlarged view of a display area including a plurality of pixels.

Particularly, FIGS. 5 and 6 illustrate a plurality of signal lines TL, a plurality of communication lines NL, a plurality of first electrodes CE1, a plurality of banks BNK, and a plurality of light emitting devices ED, but is not limited thereto. FIG. 7 is an enlarged plan view in which the plurality of second electrodes CE2 are additionally disposed in FIG. 5, for convenience, an area overlapping the second electrodes CE2 is indicated with a dotted line.

Referring to FIGS. 5 to 7, a plurality of pixels PX composed of a plurality of sub-pixels can be disposed in a display area AA. Each of the plurality of sub-pixels includes a light emitting device ED and can independently emit light. The plurality of sub-pixels can be configured in a plurality of rows and a plurality of columns and can be disposed in a matrix form, but is not limited thereto.

The plurality of sub-pixels can include a first sub-pixel SP1, a second sub-pixel SP2, and a third sub-pixel SP3. For example, the plurality of pixels (or sub-pixels) PX can include the first sub-pixel SP1, the second sub-pixel SP2, and the third sub-pixel SP3 disposed along a row direction (or a first direction X). For example, any one sub-pixel of the first sub-pixel SP1, the second sub-pixel SP2, and the third sub-pixel SP3 can be a red sub-pixel, another sub-pixel can be a green sub-pixel, and the other sub-pixel can be a blue sub-pixel. The types of the plurality of sub-pixels are examples, but is not limited thereto.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3.

The pair of first sub-pixels SP1 can be composed of a 1-1^{th} sub-pixel SP1a and a 1-2^{th} sub-pixel SP1b. The pair of second sub-pixels SP2 can be composed of a 2-1^{th} sub-pixel SP2a and a 2-2th sub-pixel SP2b. The pair of third sub-pixels SP3 can be composed of a 3-1^{th} sub-pixel SP3a and a 3-2^{th} sub-pixel SP3b. For example, one pixel PX can include the 1-1^{th} sub-pixel SP1a, the 1-2^{th} sub-pixel SP1b, the 2-1^{th} sub-pixel SP2a, the 2-2^{th} sub-pixel SP2b, the 3-1^{th} sub-pixel SP3a, and the 3-2^{th} sub-pixel SP3b, but is not limited thereto.

The plurality of sub-pixels composing one pixel PX can be variously arranged. For example, in the one pixel PX, the pair of first sub-pixels SP1 can be disposed in the same column, the pair of second sub-pixels SP2 can be disposed in the same column, and the pair of third sub-pixels SP3 can be disposed in the same column. The first sub-pixel SP1, the second sub-pixel SP2, and the third sub-pixel SP3 can be disposed in the same row. The number and arrangement of the plurality of sub-pixels composing the one pixel PX are examples, but is not limited thereto.

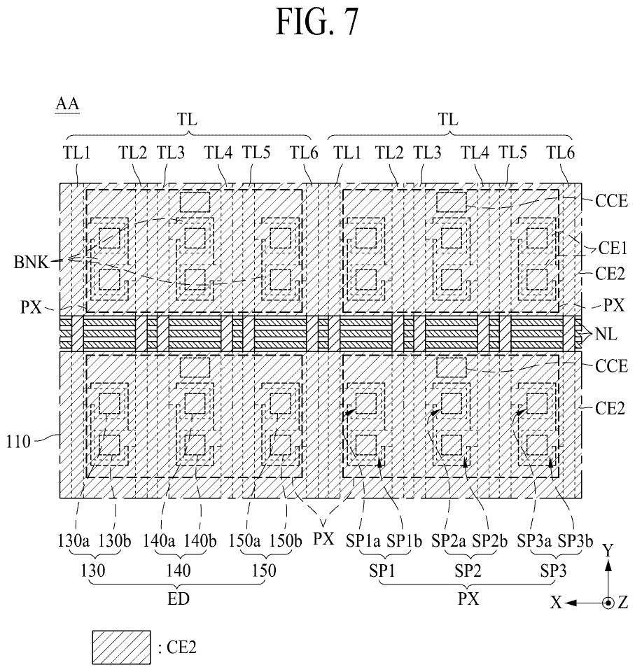

The plurality of signal lines TL can be disposed at an area between the plurality of sub-pixels. The plurality of signal lines TL can extend in a column direction (or a second direction Y) at the area between the plurality of sub-pixels. The plurality of signal lines TL can be lines that transmit an anode voltage from a pixel driving circuit (PD illustrated in FIG. 3 or a micro-driver MD) to the plurality of sub-pixels. For example, the plurality of signal lines TL can be electrically connected to the plurality of pixel driving circuits (PD illustrated in FIG. 3) and first electrodes CE1 of the plurality of sub-pixels. The anode voltage output from the pixel driving circuit (PD illustrated in FIG. 3) can be transmitted to the first electrodes CE1 of the plurality of sub-pixels through the plurality of signal lines TL. For example, the first electrode CE1 can be an electrode that is electrically connected to an anode electrode (134 illustrated in FIG. 9) of the light emitting device ED. Accordingly, the anode voltage from the signal line TL can be transmitted to the anode electrode (134 illustrated in FIG. 9) of the light emitting device ED through the first electrode CE1. For example, the first electrode CE1 can be a connection electrode, a connection electrode pattern, or a connection pattern.

Therefore, instead of forming a plurality of transistors and storage capacitors in each of the plurality of sub-pixels, a structure of the display apparatus 1000 can be simplified by using the pixel driving circuit (PD illustrated in FIG. 3) in which the plurality of pixel circuits are integrated. In addition, since the circuits disposed at each of the plurality of sub-pixels are integrated in one pixel driving circuit (PD illustrated in FIG. 3), high-efficiency and low-power driving can be possible.

The plurality of signal lines TL can include a first signal line TL1, a second signal line TL2, a third signal line TL3, a fourth signal line TL4, a fifth signal line TL5, and a sixth signal line TL6. Each of the first signal line TL1 and the second signal line TL2 can be electrically connected to each of the pair of first sub-pixels SP1. Each of the third signal line TL3 and the fourth signal line TL4 can be electrically connected to each of the pair of second sub-pixels SP2. Each of the fifth signal line TL5 and the sixth signal line TL6 can be electrically connected to each of the pair of third sub-pixels SP3.

The first signal line TL1 can be disposed at one side of the pair of first sub-pixels SP1, and the second signal line TL2 can be disposed at the other side of the pair of first sub-pixels SP1. The first signal line TL1 can be electrically connected to a first electrode CE1 of one first sub-pixel SP1 (for example, the 1-1^{th} sub-pixel SP1a) of the pair of first sub-pixels SP1. The second signal line TL2 can be electrically connected to a first electrode CE1 of the other first sub-pixel SP1 (for example, the 1-2^{th} sub-pixel SP1b) of the pair of first sub-pixels SP1.

The third signal line TL3 can be disposed at one side of the pair of second sub-pixels SP2, and the fourth signal line TL4 can be disposed at the other side of the pair of second sub-pixels SP2. For example, the third signal line TL3 can be disposed adjacent to the second signal line TL2. The third signal line TL3 can be electrically connected to a first electrode CE1 of one second sub-pixel SP2 (for example, the 2-1^{th} sub-pixel SP2a) of the pair of second sub-pixels SP2. The fourth signal line TL4 can be electrically connected to a first electrode CE1 of the other second sub-pixel SP2 (for example, the 2-2^{th} sub-pixel SP2b) of the pair of second sub-pixels SP2.

The fifth signal line TL5 can be disposed at one side of the pair of third sub-pixels SP3, and the sixth signal line TL6 can be disposed at the other side of the pair of third sub-pixels SP3. For example, the fifth signal line TL5 can be disposed adjacent to the fourth signal line TL4. The sixth signal line TL6 can be disposed adjacent to the first signal line TL1 connected to the adjacent pixel PX. The fifth signal line TL5 can be electrically connected to a first electrode CE1 of one third sub-pixel SP3 (for example, the 3-1^{th} sub-pixel SP3a) of the pair of third sub-pixels SP3. The sixth signal line TL6 can be electrically connected to a first electrode CE1 of the other third sub-pixel SP3 (for example, the 3-2^{th} sub-pixel SP3b) of the pair of third sub-pixels SP3.

The plurality of signal lines TL can be made of a conductive material. For example, the plurality of signal lines TL can be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but is not limited thereto. For another example, the plurality of signal lines TL can be made of a multilayer structure of conductive materials. For example, the plurality of signal lines TL can be made of a multilayer structure of titanium (Ti)/aluminum (Al)/titanium (Ti)/indium tin oxide (ITO), but is not limited thereto.

The plurality of communication lines NL can be disposed at an area between the plurality of pixels PX. The plurality of communication lines NL can be disposed to extend in the row direction at the area between the plurality of pixels PX. The plurality of communication lines NL are disposed at an area between the plurality of second electrodes CE2 and may not overlap the plurality of second electrodes CE2. For example, the plurality of communication lines NL can be lines (or wirings) used for short-range communication such as near field communication (NFC). The plurality of communication lines NL can function as antennas. For example, the plurality of communication lines NL can be a plurality of connection lines, but is not limited thereto.

According to an embodiment of the present disclosure, a bank BNK can be disposed at each of the plurality of sub-pixels. A plurality of banks BNK can be structures on which the plurality of light emitting devices ED are mounted. The plurality of banks BNK can guide positions of the plurality of light emitting devices ED in a transfer process of transferring the plurality of light emitting devices ED. In the transfer process of the plurality of light emitting devices ED, the plurality of light emitting devices ED can be transferred onto the plurality of banks BNK. An entire area of the light emitting device ED can overlap the bank BNK. For example, in a plan view, an entire size of the light emitting device ED can be smaller than a size of the bank BNK. For example, the plurality of banks BNK can be bank patterns, structures, or protruding patterns, or the like, but is not limited thereto.

The bank BNK of the first sub-pixel SP1, the bank BNK of the second sub-pixel SP2, and the bank BNK of the third sub-pixel SP3 can be disposed to be spaced apart from each other along the row direction (or the second direction Y). The bank BNK of the first sub-pixel SP1, the bank BNK of the second sub-pixel SP2, and the bank BNK of the third sub-pixel SP3 can be configured to be separated from each other. Accordingly, in a process of transferring the light emitting device to the sub-pixel, the banks BNK of the first sub-pixel SP1, the second sub-pixel SP2, and the third sub-pixel SP3, to which different types of light emitting devices ED are transferred, can be easily

identified, so that transfer defects in the transfer process of the light emitting devices can be prevented or minimized.

According to an embodiment of the present disclosure, the bank BNK of the 1-1^{th} sub-pixel SP1a and the bank BNK of the 1-2^{th} sub-pixel SP1b can be connected to each other, or can be formed to be spaced apart or separated from each other. For example, considering the design of the transfer process requirements, or the like, the bank BNK of the 1-1^{th} sub-pixel SP1a and the bank BNK of the 1-2^{th} sub-pixel SP1b, in which the same type of light emitting device ED is disposed, can be connected to each other, or can be spaced apart or separated from each other. In addition, the bank BNK of the 2-1^{th} sub-pixel SP2a and the bank BNK of the 2-2^{th} sub-pixel SP2b can be connected to each other, or can be formed to be spaced apart or separated from each other. The bank BNK of the 3-1^{th} sub-pixel SP3a and the bank BNK of the 3-2^{th} sub-pixel SP3b can be connected to each other, or can be formed to be spaced apart or separated from each other. Therefore, the bank BNK of the pair of first sub-pixels SP1, the bank BNK of the pair of second sub-pixels SP2, and the bank BNK of the pair of third sub-pixels SP3 can be formed in various ways, but is not limited thereto.

According to an embodiment of the present disclosure, the plurality of banks BNK can be made of an organic insulating material. The plurality of banks BNK can be composed of a single layer or multiple layers of the organic insulating material. For example, the plurality of banks BNK can be composed of a photo resist, a polyimide, or an acrylic-based material, or the like, but is not limited thereto.

The first electrode CE1 can be disposed at each of the plurality of sub-pixels. The first electrode CE1 can be disposed on the bank BNK while overlapping the bank BNK. The first electrode CE1 can be electrically connected to one of the plurality of signal lines TL. At least a portion of the first electrode CE1 can extend to an outside the bank BNK and be electrically connected to the signal line TL closest to the first electrode CE1. The portion of the first electrode CE1 can overlap the bank BNK, and the remaining portion of the first electrode CE1 may not overlap the bank BNK.

According to an embodiment of the present disclosure, a portion of the first electrode CE1 of the 1-1^{th} sub-pixel SP1a can extend to one side of the 1-1^{th} sub-pixel SP1a and can be electrically connected to the first signal line TL1, and a portion of the first electrode CE1 of the 1-2^{th} sub-pixel SP1b can extend to the other side of the 1-2^{th} sub-pixel SP1b and can be electrically connected to the second signal line TL2. A portion of the first electrode CE1 of the 2-1^{th} sub-pixel SP2a can extend to one side of the 2-1^{th} sub-pixel SP2a and can be electrically connected to the third signal line TL3, and a portion of the first electrode CE1 of the 2-2^{th} sub-pixel SP2b can extend to the other side of the 2-2^{th} sub-pixel SP2b and can be electrically connected to the fourth signal line TL4. A portion of the first electrode CE1 of the 3-1^{th} sub-pixel SP3a can extend to one side of the 3-1^{th} sub-pixel SP3a and can be electrically connected to the fifth signal line TL5, and a portion of the first electrode CE1 of the 3-2^{th} sub-pixel SP3b can extend to the other side of the 3-2^{th} sub-pixel SP3b and can be electrically connected to the sixth signal line TL6.

The first electrode CE1 can be electrically connected to the anode electrode (or anode terminal) (134 illustrated in FIG. 9) of the light emitting device ED. The anode voltage from the pixel driving circuit (PD illustrated in FIG. 3) can be sequentially transmitted to the light emitting device ED through the signal line TL and the first electrode CE1. The pixel driving circuit (PD illustrated in FIG. 3) can apply the same voltage (or anode voltage) to the first electrode CE1 of each of the plurality of sub-pixels, but is not limited thereto. For example, the pixel driving circuit (PD illustrated in FIG. 3) can be configured to apply different voltages to the first electrode CE1 of each of the plurality of sub-pixels based on an image displayed on the corresponding sub-pixel. For example, different voltages can be applied to the first electrodes CE1 of each of the plurality of sub-pixels. Accordingly, the first electrode CE1 can be a pixel electrode, but is not limited thereto.

The first electrode CE1 can be composed of a conductive material. For example, the first electrode CE1 can be formed integrally with the plurality of signal lines TL. For example, the first electrode CE1 can be composed of the same conductive material as the plurality of signal lines TL, but is not limited thereto. As an embodiment of the present disclosure, the first electrode CE1 can be composed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but is not limited thereto. As another embodiment of the present disclosure, the first electrode CE1 can be composed of a multilayer structure of a conductive material. For example, the plurality of first electrodes CE1 can be composed of a multilayer structure of titanium (Ti)/aluminum (Al)/titanium (Ti)/indium tin oxide (ITO), but is not limited thereto.

The plurality of light emitting devices ED can be disposed at the first electrode CE1 so as to overlap the bank BNK and the first electrode CE1. An entire area of the plurality of light emitting

devices ED can overlap the bank BNK and the first electrode CE1. The plurality of light emitting devices ED can be in contact with the first electrode CE1 so as to overlap the bank BNK and the first electrode CE1.

The plurality of light emitting devices ED can disposed at the first electrode CE1 and can be electrically connected to the first electrode CE1. Therefore, the light emitting devices ED can emit light by receiving the anode voltage from the pixel driving circuit PD through the signal line TL and the first electrode CE1.

The plurality of light emitting devices ED can include a first light emitting device 130, a second light emitting device 140, and a third light emitting device 150.

The first light emitting device 130 can be disposed at the first sub-pixel SP1. The second light emitting device 140 can be disposed at the second sub-pixel SP2. The third light emitting device 150 can be disposed at the third sub-pixel SP3. For example, any one of the first light emitting device 130, the second light emitting device 140, and the third light emitting device 150 can be a red light emitting device, another light emitting device can be a green light emitting device, and the other light emitting device can be a blue light emitting device, but is not limited thereto. Accordingly, red light, green light, and blue light emitted from the plurality of light emitting devices ED can be combined to implement various colors of light including white. The types of the plurality of light emitting devices ED are examples, but is not limited thereto.

The first light emitting device 130 can include a 1-1^{th} light emitting device 130a disposed at a 1-1^{th} sub-pixel SP1a and a 1-2^{th} light emitting device 130b disposed at a 1-2^{th} sub-pixel SP1b. The second light emitting device 140 can include a 2-1^{th} light emitting device 140a disposed at a 2-1^{th} sub-pixel SP2a and a 2-2^{th} light emitting device 140b disposed at a 2-2^{th} sub-pixel SP2b. The third light emitting device 150 can include a 3-1^{th} light emitting device 150a disposed at a 3-1^{th} sub-pixel SP3a and a 3-2^{th} light emitting device 150b disposed at a 3-2^{th} sub-pixel SP3b.

A second electrode CE2 can be disposed at each of the plurality of sub-pixels. The second electrode CE2 can be disposed over the light emitting device ED. The second electrode CE2 can be electrically connected to the pixel driving circuit (PD illustrated in FIG. 3) through a plurality of contact electrodes CCE. The second electrode CE2 can be electrically connected to a cathode electrode (or cathode terminal) (135 illustrated in FIG. 9) of the light emitting device ED to transmit a cathode voltage (or low-potential power voltage) from the pixel driving circuit (PD illustrated in FIG. 3) to the light emitting device ED.

According to an embodiment of the present disclosure, the cathode voltage (or a common electrode voltage) applied to the second electrode CE2 of each of the plurality of sub-pixels can be the same. For example, the cathode voltage can be commonly applied to the second electrode CE2 of each of the plurality of sub-pixels and the cathode electrode (135 illustrated in FIG. 9) of the light emitting device ED. Accordingly, the second electrode CE2 can be a common electrode, a common electrode pattern, a common cathode electrode, a common cathode electrode pattern, a common divided electrode, or a common divided electrode pattern, but is not limited thereto.

According to another embodiment of the present disclosure, the cathode voltage applied to the second electrode CE2 of each of the plurality of sub-pixels can be changed based on a reference voltage (Vref illustrated in FIG. 4). For example, the cathode voltage can be adjusted (or varied) according to screen brightness based on a user operation (or setting).

The second electrode CE2 according to an embodiment of the present disclosure can have a size corresponding to one row (or a horizontal line). For example, the second electrode CE2 can have a width corresponding to one row and can extend along the row direction (or the first direction X). For example, the second electrode CE2 can be commonly connected to the light emitting device ED in each of the plurality of pixels PX disposed along the row direction. For example, the second electrode CE2 can be commonly connected to a cathode electrode (135 illustrated in FIG. 9) of the light emitting device ED in each of 16 pixels PX disposed along the row direction, but is not limited thereto. For example, the second electrode CE2 can be commonly connected to the cathode electrode (135 illustrated in FIG. 9) of 96 light emitting devices ED disposed along the row direction, but is not limited thereto. For example, the second electrode CE2 can be commonly connected to the cathode electrode (135 illustrated in FIG. 9) of 192 light emitting devices ED in one row, but is not limited thereto.

According to another embodiment of the present disclosure, some of the second electrodes CE2 of each of the plurality of sub-pixels can be disposed to be spaced apart from or separated from each other. For example, the second electrodes CE2 connected to the pixels PX of a n^{th} row and the second electrodes CE2 connected to the pixels PX of a n+1^{th} row can be disposed to be spaced apart from or separated from each other. As an embodiment of the present disclosure, the plurality of second electrodes CE2 can be disposed to be spaced apart from each other with a plurality of communication lines NL extending in the row direction therebetween. Accordingly, the number of the plurality of sub-pixels can be greater than the number of the plurality of second electrodes CE2.

The plurality of second electrodes CE2 can be composed of a transparent conductive material, but is not limited thereto. The plurality of second electrodes CE2 can be composed of a transparent conductive material so that light emitted from the light emitting device ED can be directed toward an upper portion of the second electrodes CE2. For example, the second electrodes CE2 can be composed of a transparent conductive material such as indium tin oxide (ITO), indium zinc oxide (IZO), indium gallium zinc oxide (IGZO), or the like, but is not limited thereto.

The plurality of contact electrodes CCE can be disposed on the substrate 110. For example, the plurality of contact electrodes CCE can be disposed to be spaced apart from the plurality of banks BNK and the plurality of signal lines TL. Each of the plurality of second electrodes CE2 can overlap at least one contact electrode CCE. For example, one second electrode CE2 can overlap the plurality of contact electrodes CCE.

The plurality of contact electrodes CCE can be electrically connected to the plurality of second electrodes CE2. The plurality of contact electrodes CCE can be disposed between the substrate 110 and the plurality of second electrodes CE2 and configured to transmit a cathode voltage supplied from the pixel driving circuit (PD illustrated in FIG. 3) through a low-potential power line to the second electrodes CE2.

According to an embodiment of the present disclosure, when the light emitting device ED is configured as a micro light emitting diode chip, a plurality of micro light emitting diode chips can be formed on a wafer, and the micro light emitting diode chips can be transferred to a substrate 110 to manufacture a display panel 100. In the process of transferring a plurality of light emitting devices ED having a micro size (or fine size) from the wafer to the substrate 110, various defects can occur. For example, in some sub-pixels, a defect can occur in which the light emitting device ED is not transferred, and in other sub-pixels, a defect can occur in which the light emitting device ED is transferred out of its proper position due to an alignment error. In addition, the transfer process can proceed normally, but the transferred light emitting device ED itself can be defective. Therefore, in consideration of defects that can occur during the transfer process of the plurality of light emitting devices ED, a plurality of light emitting devices ED of the same type can be transferred to one sub-pixel. A lighting test of the plurality of light emitting devices ED can be performed, and only one light emitting device ED that is finally determined to be normal can be used.

According to an embodiment of the present disclosure, the 1-1^{th} light emitting device 130a and the 1-2^{th} light emitting device 130b can be transferred together to one pixel PX, and can be inspected for defects therein. As an embodiment of the present disclosure, when the 1-1^{th} light emitting device 130a and the 1-2^{th} light emitting device 130b are determined to be normal, only the 1-1^{th} light emitting device 130a can be used, and the 1-2^{th} light emitting device 130b can be unused. In another embodiment of the present disclosure, if only the 1-2^{th} light emitting device 130b among the 1-1^{th} light emitting device 130a and the 1-2^{th} light emitting device 130b is determined to be normal, the 1-1^{th} light emitting device 130a is not used, and only the 1-2^{th} light emitting device 130b can be used. Therefore, even if multiple light emitting devices EDs of the same type are transferred to one pixel PX, only one light emitting device ED can ultimately be used.

According to an embodiment of the present disclosure, any one of a pair of light emitting devices ED can be a main (or a primary) light emitting device ED, and the other light emitting device ED can be a redundancy light emitting device ED. The redundancy light emitting device ED can be a spare light emitting device ED that is transferred in preparation for a failure of the main light emitting device ED. When the main light emitting device ED fails, the redundancy light emitting device ED can be used as a replacement for the main light emitting device ED. Therefore, by transferring the main light emitting device ED and the redundancy light emitting device ED together to one pixel PX, it is possible to minimize a deterioration in display quality due to a failure of the main light emitting device ED and the redundancy light emitting device ED. For example, the 1-1^{th} light emitting device 130a, the 2-1^{th} light emitting device 140a, and the 3-1^{th} light emitting device 150a transferred to one pixel PX can be used as the main light emitting device ED, and the 1-2^{th} light emitting device 130b, the 2-2^{th} light emitting device 140b, and the 3-2^{th} light emitting device 150b can be used as the redundancy light emitting device ED.

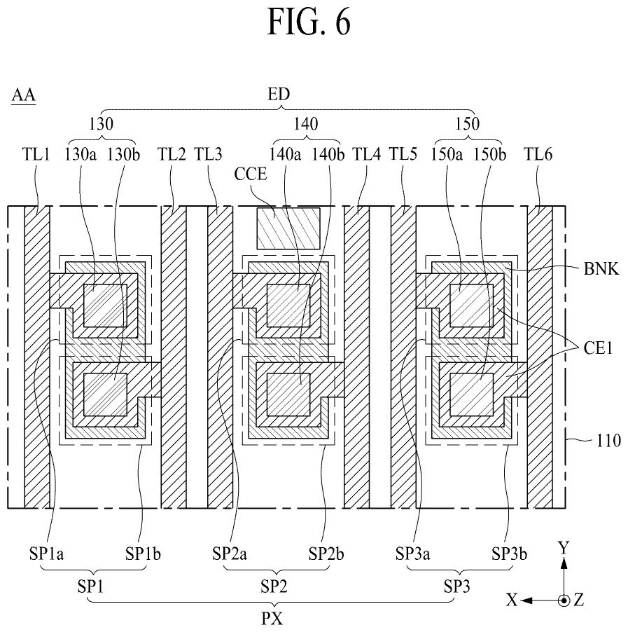

FIG. 8 is a cross-sectional view taken along line I-I′ illustrated in FIG. 2. FIG. 9 is a cross-sectional view of a first light emitting device according to an embodiment of the present disclosure. For example, FIG. 8 is a cross-sectional view of a display area AA, a first non-display area NA, a bending area BA, and a second non-display area NA2 taken along line I-I′ illustrated in FIG. 2, and FIG. 9 is a cross-sectional view of a portion of the display area AA.

Referring to FIG. 8, a buffer layer 111 can be disposed at the remaining area of the substrate 110 excluding the bending area BA. The buffer layer 111 can include a first buffer layer 111a and a second buffer layer 111b.

The first buffer layer 111a and the second buffer layer 111b can be disposed at the display area AA, the first non-display area NA1, and the second non-display area NA2. The first buffer layer 111a and the second buffer layer 111b can reduce penetration of moisture or impurities through the substrate 110. The first buffer layer 111a and the second buffer layer 111b can be composed of an inorganic insulating material. For example, the first buffer layer 111a and the second buffer layer 111b can be made of a single layer or multiple layers of silicon oxide (SiOx) or silicon nitride (SiNx), but is not limited thereto.

According to an embodiment of the present disclosure, a portion of the first buffer layer 111a and the second buffer layer 111b on the bending area BA can be removed. An upper surface of the substrate 110 located at the bending area BA can be exposed without being covered by the first buffer layer 111a and the second buffer layer 111b. Since the portion of the first buffer layer 111a and the second buffer layer 111b made of an inorganic insulating material is removed at the bending area BA, cracks generated at the first buffer layer 111a and the second buffer layer 111b can be prevented or minimized when the bending area BA is bent.

A plurality of alignment keys MK can be disposed between the first buffer layer 111a and the second buffer layer 111b. The plurality of alignment keys MK can be configured to identify (or align) a position of pixel driving circuit PD during a manufacturing process of the display panel 100. For example, the plurality of alignment keys MK can be configured to align the position of pixel driving circuit PD transferred onto an adhesive layer 112. For example, the plurality of alignment keys MK can be omitted, but is not limited thereto.

The adhesive layer 112 can be disposed on the second buffer layer 111b. The adhesive layer 112 can be disposed at the display area AA, the first non-display area NA1, the bending area BA, and the second non-display area NA2. For example, in the non-display areas NA1 and NA2 including the bending area BA, at least a portion of the adhesive layer 112 can be removed. For example, the adhesive layer 112 can be made of any one of a polymer, an epoxy resin, a UV-curable resin, a polyimide-based material, an acrylate-based material, a urethane-based material, and a polydimethylsiloxane (PDMS), but is not limited thereto.

In the display area AA, the pixel driving circuit PD can be disposed on the adhesive layer 112. The pixel driving circuit PD can be supported by the buffer layer 111. When the pixel driving circuit PD is implemented as a driving driver (or a driving driver integrated circuit or a driving driver chip), the driving driver can be mounted on the adhesive layer 112 by a transfer process, but is not limited thereto.

A protective layer 113 can be disposed on the adhesive layer 112 and the pixel driving circuit PD. The protective layer 113 can include a first protective layer 113a and a second protective layer 113b. For example, the first protective layer 113a and the second protective layer 113b can be disposed on the adhesive layer 112 and the pixel driving circuit PD. The first protective layer 113a and the second protective layer 113b can be disposed to surround a side surface (or lateral surface) of the pixel driving circuit PD, but is not limited thereto. For example, the second protective layer 113b can be disposed to cover at least a portion of an upper surface of the pixel driving circuit PD. For example, at least one of the first protective layer 113a and the second protective layer 113b disposed on the bending area BA can be omitted. For example, the first protective layer 113a can be entirely disposed at the display area AA and the non-display area NA, and the second protective layer 113b can be partially disposed at the display area AA, the first non-display area NA1, and the second non-display area NA2, and may not be disposed at the bending area BA. For example, the second protective layer 113b (or a portion of the first protective layer 113a) at the bending area BA can be removed, but is not limited thereto.

The first protective layer 113a and the second protective layer 113b can be composed of an organic insulating material, but is not limited thereto. For example, the first protective layer 113a and the second protective layer 113b can be composed of a photo resist, a polyimide, or a photo acryl-based material, or the like, but is not limited thereto. For example, the first protective layer 113a and the second protective layer 113b can be an overcoating layer, an insulating layer, or an organic insulating layer, but is not limited thereto.

According to an embodiment of the present disclosure, a wiring layer (or pixel wiring layer) can be disposed on the protective layer 113. For example, the wiring layer can be configured to surround or cover the pixel driving circuit PD. The wiring layer can include a plurality of first connection lines 121.

The plurality of first connection lines 121 can be disposed on the protective layer 113. For example, the plurality of first connection lines 121 can be disposed on the second protective layer 113b at the display area AA. The plurality of first connection lines 121 can be lines (or intermediate lines or jumping lines) configured to electrically connect the pixel driving circuit PD to other components and/or lines in different layers. For example, the pixel driving circuit PD can be electrically connected to a plurality of signal lines TL and a plurality of contact electrodes CCE, or the like through the plurality of first connection lines 121.

The plurality of first connection lines 121 can include a 1-1^{th} connection line 121a, a 1-2^{th} connection line 121b, a 1-3^{th} connection line 121c, and a 1-4^{th} connection line 121d, but is not limited thereto. For example, the plurality of 1-1^{th} connection lines 121a can be disposed on the second protective layer 113b. The plurality of 1-1^{th} connection lines 121a can be configured to be electrically connected to the pixel driving circuit PD. The plurality of 1-1^{th} connection lines 121a can be configured to transmit a voltage output from the pixel driving circuit PD to the first electrode CE1 or the second electrode CE2.

A third protective layer 114 can be disposed on the second protective layer 113b. The third protective layer 114 can be entirely disposed at the display area AA and the non-display area NA. In the bending area BA, the third protective layer 114 can cover or enclose side surfaces (or lateral surfaces) of the second protective layer 113b and the upper surface of the first protective layer 113a. The third protective layer 114 can be composed of an organic insulating material. For example, the third protective layer 114 can be composed of a photo resist, a polyimide, or a photo acryl-based material, or the like, but is not limited thereto. For example, the first protective layer 113a, the second protective layer 113b, and the third protective layer 114 can be composed of the same material, but is not limited thereto.

The plurality of 1-2^{th} connection lines 121b can be disposed on the third protective layer 114. The plurality of 1-2^{th} connection lines 121b can be connected to the pixel driving circuit PD through the 1-1^{th} connection line 121a or can be directly connected to the pixel driving circuit PD. For example, a portion of the 1-2^{th} connection line 121b can be directly connected to the pixel driving circuit PD through a contact hole of the third protective layer 114. Another portion of the 1-2^{th} connection line 121b can be electrically connected to the 1-1^{th} connection line 121a through a contact hole of the third protective layer 114. However, embodiments of the present disclosure are not limited thereto. As an embodiment of the present disclosure, a voltage output from the pixel driving circuit PD can be transmitted to the first electrode CE1 or the second electrode CE2 through the plurality of 1-2^{th} connection lines 121b and other connection lines.

The display apparatus 1000 according to an embodiment of the present disclosure can further include an insulating layer 115 in the wiring layer. The insulating layer 115 can be configured to electrically insulate the plurality of first connection lines 121 and cover the plurality of first connection lines 121. For example, the insulating layer 115 can include a plurality of insulating layers 115a, 115b, and 115c or can include first to third insulating layers 115a, 115b, and 115c.

According to an embodiment of the present disclosure, the first insulating layer 115a can be disposed on the plurality of 1-2^{th} connection lines 121b. The first insulating layer 115a can be entirely disposed at the display area AA and the non-display area NA, but is not limited thereto. The first insulating layer 115a can be composed of an organic insulating material, but is not limited thereto. For example, the first insulating layer 115a can be composed of a photo resist, a polyimide, or a photo acryl-based material, or the like, but is not limited thereto.

The plurality of 1-3^{th} connection lines 121c can be disposed on the first insulating layer 115a. The plurality of 1-3^{th} connection lines 121c can be electrically connected to the plurality of 1-2^{th} connection lines 121b. For example, the 1-3^{th} connection line 121c can be electrically connected to the 1-2^{th} connection line 121b through a contact hole of the first insulating layer 115a.

A second insulating layer 115b can be disposed on the plurality of 1-3^{th} connection lines 121c. The second insulating layer 115b can be disposed at the remaining area except for the bending area BA, but is not limited thereto. The second insulating layer 115b can be disposed at the display area AA, the first non-display area NA1, and the second non-display area NA2, but is not limited thereto. For example, at least a portion of the second insulating layer 115b disposed at the bending area BA can be removed. The second insulating layer 115b can be composed of an organic insulating material, but is not limited thereto. For example, the second insulating layer 115b can be composed of a photo resist, polyimide, or photo acryl-based material, or the like, but is not limited thereto.

The plurality of 1-4^{th} connection lines 121d can be disposed on the second insulating layer 115b. The plurality of 1-4^{th} connection lines 121d can be electrically connected to the plurality of 1-3^{th} connection lines 121c. For example, the 1-4^{th} connection line 121d can be electrically connected to the 1-3^{th} connection line 121c through a contact hole of the second insulating layer 115b.

The 1-4^{th} connection line 121d can be connected to the contact electrode CCE through a contact hole of the third insulating layer 115c, and accordingly, the contact electrode CCE and the pixel driving circuit PD can be electrically connected by the first connection line 121. For example, the contact electrode CCE connected to the second electrode CE2 can be electrically connected to the pixel driving circuit PD through the 1-4^{th} connection line 121d, the 1-3^{th} connection line 121c, the 1-2^{th} connection line 121b, and the 1-1^{th} connection line 121a.

The 1-4^{th} connection line 121d can be directly connected to the signal line TL through a contact hole provided at the third insulating layer 115c, or can be electrically connected to the signal line TL through another additional line or electrode, and accordingly, the signal line TL and the pixel driving circuit PD can be electrically connected by the first connection line 121.

A plurality of second connection lines 122 can be disposed on the protective layer 113 in the non-display area NA. For example, the plurality of second connection lines 122 can be disposed on the second protective layer 113b in the non-display area NA. The plurality of second connection lines 122 can be lines for transmitting signals transmitted from a flexible circuit board (310 illustrated in FIG. 2) and a printed circuit board (330 illustrated in FIG. 2) through a pad portion (PAD illustrated in FIG. 2) to the pixel driving circuit PD in the display area AA.

According to an embodiment of the present disclosure, the plurality of second connection lines 122 can be electrically connected to a plurality of pad electrodes PE and can receive signals from the flexible circuit board (310 illustrated in FIG. 2) and the printed circuit board (330 illustrated in FIG. 2).

According to an embodiment of the present disclosure, the plurality of second connection lines 122 can be configured to extend from the pad portion (PAD illustrated in FIG. 2) toward the display area AA and transmit the signals to the lines of the display area AA. In this case, the plurality of second connection lines 122 can function as link lines (LL illustrated in FIG. 3).

The plurality of second connection lines 122 can include a 2-1^{th} connection line 122 a, a 2-2th connection line 122b, a 2-3^{th} connection line 122c, and a 2-4^{th} connection line 122d.

A plurality of 2-1^{th} connection lines 122a can be disposed on the protection layer 113. For example, the plurality of 2-1^{th} connection lines 122a can be disposed on the second protection layer 113b. The plurality of 2-1^{th} connection lines 122a can extend from the second non-display area NA2 to the bending area BA and the first non-display area NA1. The plurality of 2-1^{th} connection lines 122a can be configured to transmit the signals transmitted from the flexible circuit board (310 illustrated in FIG. 2) and the printed circuit board (330 illustrated in FIG. 2) through the pad portion (PAD illustrated in FIG. 2) to the pixel driving circuit PD of the display area AA.

According to an embodiment of the present disclosure, the plurality of 2-1^{th} connection lines 122a can be electrically connected to the pad electrode PE and the pixel driving circuit PD, respectively. For example, the 2-1^{th} connection line 122a can extend to the display area AA and can be directly connected to the pixel driving circuit PD within the display area AA, or can be

electrically connected to the pixel driving circuit PD through other additional lines or electrodes. In addition, the 2-1^{th} connection line 122a can be electrically connected to the pad electrode PE within the second non-display area NA2 through the 2-2^{th} connection line 122b, the 2-3^{th} connection line 122c, and the 2-4^{th} connection line 122d. Therefore, the pixel driving circuit PD and the pad electrode PE can be electrically connected by the second connection lines 122.

A plurality of 2-2^{th} connection lines 122b can be disposed on the third protective layer 114. The plurality of 2-2^{th} connection lines 122b can be disposed at the second non-display area NA2. The 2-2^{th} connection line 122b can be electrically connected to the 2-1^{th} connection line 122a through the contact hole of the third protective layer 114. Accordingly, signals from the flexible circuit board (310 illustrated in FIG. 2) and the printed circuit board (330 illustrated in FIG. 2) can be transmitted to the 2-1^{th} connection line 122a through the 2-2^{th} connection line 122b.

The 2-3^{th} connection line 122c can be disposed on the first insulating layer 115a. The 2-3^{th} connection line 122c can be disposed at the second non-display area NA2. The 2-3^{th} connection line 122c can be electrically connected to the 2-2^{th} connection line 122b through the contact hole of the first insulating layer 115a. Therefore, signals from the flexible circuit board (310 illustrated in FIG. 2) and the printed circuit board (330 illustrated in FIG. 2) can be transmitted to the 2-1^{th} connection line 122a through the 2-3^{th} connection line 122c and the 2-2^{th} connection line 122b.

The 2-4^{th} connection line 122 d can be disposed on the second insulating layer 115 b. The 2-4^{th}connection line 122d can be disposed at the second non-display area NA2. The 2-4^{th} connection line 122d can be electrically connected to the 2-3^{th} connection line 122c through the contact hole of the second insulating layer 115b. The 2-4^{th} connection line 122d can be electrically connected to the pad electrode PE through the contact hole of the third insulating layer 115c.

According to an embodiment of the present disclosure, signals from the flexible circuit board (310 illustrated in FIG. 2) and the printed circuit board (330 illustrated in FIG. 2) can be transmitted to the 2-1^{th} connection line 122a through the 2-4^{th} connection line 122d, the 2-3^{th} connection line 122c, and the 2-2^{th} connection line 122b. For example, the 2-2^{th} connection line 122a can extend to the display area AA through the bending area BA, and can be electrically connected to the pixel driving circuit PD in the display area AA. Therefore, the pad electrode PE provided in the second non-display area NA2 can be electrically connected to the pixel driving circuit PD provided in the display area AA through the 2-4^{th} connection line 122d, the 2-3^{th} connection line 122c, the 2-2^{th} connection line 122b, and the 2-1^{th} connection line 122a provided in the bending area BA.

The plurality of first connection lines 121 and the plurality of second connection lines 122 can be formed of a conductive material having excellent ductility characteristics or any one of various conductive materials used in the display area AA. As an embodiment of the present disclosure, the second connection line 122 in which a portion is disposed at the bending area BA can be composed of a conductive material having excellent ductility, such as gold (Au), silver (Ag), or aluminum (Al), but is not limited thereto. As another embodiment of the present disclosure, the plurality of first connection lines 121 and the plurality of second connection lines 122 can be composed of molybdenum (Mo), chromium (Cr), titanium (Ti), nickel (Ni), neodymium (Nd), copper (Cu), and an alloy of silver (Ag) and magnesium (Mg), or an alloy thereof, but is not limited thereto.

The third insulating layer 115c can be disposed on the plurality of first connection lines 121 and the plurality of second connection lines 122. The third insulating layer 115c can be disposed at the remaining area except for the bending area BA, but is not limited thereto. The third insulating layer 115c can be disposed at the display area AA, the first non-display area NA1, and the second non-display area NA2. At least a portion of the third insulating layer 115c in the bending area BA can be removed. The third insulating layer 115c can be composed of an organic insulating material, but is not limited thereto. For example, the third insulating layer 115c can be composed of a photo resist, polyimide, or photo acryl-based material, or the like, but is not limited thereto.

A plurality of banks BNK can be disposed on the third insulating layer 115c in the display area AA. The plurality of banks BNK can be disposed to overlap each of the plurality of sub-pixels. The plurality of banks BNK may not be disposed in the first non-display area NA1, the second non-display area NA2, and the bending area BA. One or more light emitting devices ED of the same type can be disposed on each of the plurality of banks BNK.

A plurality of signal lines TL can be disposed on the third insulating layer 115c in the display area AA. The plurality of signal lines TL can be disposed at an area between the plurality of banks BNK. For example, the plurality of signal lines TL can be disposed adjacent to any one of the plurality of banks BNK. Each of the plurality of signal lines TL can be electrically connected to the first connection line 121, for example, the 1-4^{th} connection line 121d.

A plurality of contact electrodes CCE can be disposed on the third insulating layer 115c in the display area AA. The plurality of contact electrodes CCE can supply a cathode voltage from

the pixel driving circuit PD to the second electrode CE2. Each of the plurality of contact electrodes CCE can be electrically connected to the first connection line 121, for example, the 1-4^{th} connection line 121d.

The first electrode CE1 can be disposed on the bank BNK. For example, the first electrode CE1 can be disposed to extend from adjacent signal line TL toward an upper portion of the bank BNK. The first electrode CE1 can be disposed on an upper surface of the bank BNK and a side surface of the bank BNK. For example, the first electrode CE1 can be disposed to extend from the signal line TL on the third insulating layer 115c to the side surface of the bank BNK and the upper surface of the bank BNK. The first electrode CE1 can be a contact electrode. The first electrode CE1 can be formed integrally with the signal line TL.

Referring to FIG. 9, the first electrode CE1 can be composed of a plurality of conductive layers. For example, the first electrode CE1 can include a first conductive layer CE1a, a second conductive layer CE1b, a third conductive layer CE1c, and a fourth conductive layer CE1d, but is not limited thereto.

The first conductive layer CE1a can be disposed on the bank BNK. The second conductive layer CE1b can be disposed on the first conductive layer CE1a. The third conductive layer CE1c can be disposed on the second conductive layer CE1b. The fourth conductive layer CE1d can be disposed on the third conductive layer CE1c. For example, each of the first conductive layer CE1a, the second conductive layer CE1b, the third conductive layer CE1c, and the fourth conductive layer CE1d can be composed of titanium (Ti), molybdenum (Mo), aluminum (Al), or titanium (Ti) and indium tin oxide (ITO), but is not limited thereto.

According to an embodiment of the present disclosure, some of the conductive layers having high reflection efficiency, among the plurality of conductive layers configuring the first electrode CE1, can be configured as an alignment key and/or a reflective plate (or reflector) for aligning the light emitting device ED. For example, the second conductive layer CE1b among the plurality of conductive layers configuring the first electrode CE1 can include a reflective material. For example, the second conductive layer CE1b can include aluminum (Al), but is not limited thereto. Accordingly, the second conductive layer CE1b can be configured as the reflective plate. In addition, due to the high reflection efficiency of the second conductive layer CE1b, it can be easy to identify in a manufacturing process, and thus, a position or a transfer position of the light emitting device ED can be aligned based on the second conductive layer CE1b.

According to an embodiment of the present disclosure, in order to configure the second conductive layer CE1b as the reflective plate, the third conductive layer CE1c and the fourth conductive layer CE1d covering the second conductive layer CE1b can be partially removed or etched. For example, a portion of the third conductive layer CE1c and the fourth conductive layer CE1d disposed on the bank BNK can be removed or etched, thereby exposing an upper surface of the second conductive layer CE1b. For example, a center portion and a border portion (or a periphery portion) of the third conductive layer CE1c and the fourth conductive layer CE1d, where the solder pattern SDP is disposed, may not be removed, and the remaining portions other than these can be removed. For example, the border portion (or periphery portion) and the center portion of each of the third conductive layer CE1c which is made of titanium (Ti) and the fourth conductive layer CE1d which is made of indium tin oxide (ITO) may not be removed or etched. Accordingly, corrosion of other conductive layers configuring the first electrode CE1 can be prevented or minimized by an etchant (for example, a TMAH (tetramethyl ammonium hydroxide) solution) used in a mask process (or patterning process) of the first electrode CE1.

According to an embodiment of the present disclosure, the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer, such as indium tin oxide (ITO) or indium zinc oxide (IZO), which has good adhesion to the solder pattern SDP and has corrosion resistance and acid resistance. However, embodiments of the present disclosure are not limited thereto.

The first conductive layer CE1a, the second conductive layer CE1b, the third conductive layer CE1c, and the fourth conductive layer CE1d can be sequentially deposited and then patterned by a photolithography process and an etching process, but is not limited thereto.

As can be seen in FIGS. 8 and 9, according to an embodiment of the present disclosure, the signal line TL, the contact electrode CCE, and the pad electrode PE disposed at the same layer as the first electrode CE1 can be configured with a multilayer structure of a conductive material, but is not limited thereto. For example, the signal line TL, the contact electrode CCE, and the pad electrode PE can be configured with a multilayer structure of indium tin oxide (ITO)/titanium (Ti)/aluminum (Al)/titanium (Ti), but is not limited thereto.

According to an embodiment of the present disclosure, the solder pattern SDP can be disposed on the first electrode CE1 in each of the plurality of sub-pixels. The solder pattern SDP can bond the light emitting device ED to the first electrode CE1. The first electrode CE1 and the light emitting device ED can be electrically connected through eutectic bonding using the solder pattern SDP, but is not limited thereto. For example, when the solder pattern SDP is made of indium (In) and the anode electrode 134 of the light emitting device ED is made of gold (Au), the solder pattern SDP and the anode electrode 134 can be bonded by applying heat and pressure in a transfer process of the light emitting device ED. The light emitting device ED can be bonded to the solder pattern SDP and the first electrode CE1 through eutectic bonding without a separate adhesive. For example, the solder pattern SDP can be composed of indium (In), tin (Sn), or an alloy thereof, but is not limited thereto. For example, the solder pattern SDP can be a contact pattern, a bonding pad, or a joining pad, or the like, but is not limited thereto.

According to an embodiment of the present disclosure, a passivation layer 116 can be disposed on the wiring layer. For example, the passivation layer 116 can be configured to cover the wiring layer in the display area AA. For example, the passivation layer 116 can be disposed on the plurality of signal lines TL, the plurality of first electrodes CE1, the plurality of contact electrodes CCE, and the third insulating layer 115c. For example, the passivation layer 116 can be disposed at the display area AA, the first non-display area NA1, and the second non-display area NA2. At least a portion of the passivation layer 116 disposed at the bending area BA can be removed. A portion of the passivation layer 116 covering the plurality of pad electrodes PE in the second non-display area NA2 can be removed. A portion of the passivation layer 116 covering the plurality of contact electrodes CCE in the display area AA can be removed. The passivation layer 116 covering the solder pattern SDP in the display area AA can be removed. The passivation layer 116 can cover the first electrode CE1. The passivation layer 116 can cover a portion of the upper surface of the exposed second conductive layer CE1b.

The passivation layer 116 is disposed to expose at least a portion of the plurality of pad electrodes PE, the plurality of contact electrodes CCE, and the solder pattern SDP while covering the remaining area, so as to reduce the penetration of moisture or impurities into the light emitting device ED. For example, the passivation layer 116 can be composed of a single layer or multiple layers of silicon oxide (SiOx) or silicon nitride (SiNx), but is not limited thereto. For example, the passivation layer 116 can be a protective layer, an insulating layer, or an inorganic insulating layer, or the like, but is not limited thereto. For example, the passivation layer 116 can include a hole exposing the solder pattern SDP and a hole exposing the contact electrode CCE.

In each of the plurality of sub-pixels, the light emitting device ED can be disposed on the solder pattern SDP. A first light emitting device 130 can be disposed in a first sub-pixel SP1. A second light emitting device 140 can be disposed in a second sub-pixel SP2. A third light emitting device 150 can be disposed in a third sub-pixel SP3.

The light emitting device ED can be formed on a silicon wafer by a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, or the like, but is not limited thereto.

Referring to FIG. 9, the first light emitting device 130 can include an anode electrode 134, a first semiconductor layer 131, an active layer 132, a second semiconductor layer 133, a cathode electrode 135, and an encapsulation film 136, but is not limited thereto. For example, the encapsulation film 136 may not be included in the first light emitting device 130.

The first semiconductor layer 131 can be disposed on a solder pattern SDP. The second semiconductor layer 133 can be disposed on the first semiconductor layer 131.

According to an embodiment of the present disclosure, one of the first semiconductor layer 131 and the second semiconductor layer 133 can be implemented as a compound semiconductor of a group III-V or a group II-VI, or the like, and can be doped with an impurity (or dopant). For example, one of the first semiconductor layer 131 and the second semiconductor layer 133 can be a semiconductor layer doped with an n-type impurity, and the other can be a semiconductor layer doped with a p-type impurity, but is not limited thereto. For example, one or more of the first semiconductor layer 131 and the second semiconductor layer 133 can be a layer doped with an n-type or p-type impurity in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), or the like, but is not limited thereto. For example, the n-type impurity can be silicon (Si), germanium (Ge), selenium (Se), carbon (C), tellurium (Te), or tin (Sn), or the like, but is not limited thereto. For example, the p-type impurity can be magnesium (Mg), zinc (Zn), calcium (Ca), strontium (Sr), barium (Ba), or beryllium (Be), or the like, but is not limited thereto.

According to an embodiment of the present disclosure, the first semiconductor layer 131

and the second semiconductor layer 133 can be a nitride semiconductor including the n-type impurity and a nitride semiconductor including the p-type impurity, respectively, but is not limited thereto. For example, the first semiconductor layer 131 can be a nitride semiconductor including the p-type impurity, and the second semiconductor layer 133 can be a nitride semiconductor including the n-type impurity, but is not limited thereto.

The active layer 132 can be disposed (or interposed) between the first semiconductor layer 131 and the second semiconductor layer 133. The active layer 132 can receive holes and electrons from the first semiconductor layer 131 and the second semiconductor layer 133 to emit light. For example, the active layer 132 can be configured as one of a single well structure, a multi-well structure, a single quantum well structure, a multi-quantum well (MQW) structure, a quantum dot structure, and a quantum line structure, but is not limited thereto. For example, the active layer 132 can be configured as indium gallium nitride (InGaN) or gallium nitride (GaN), or the like, but is not limited thereto.

According to another embodiment of the present disclosure, the active layer 132 can include a multi-quantum well structure having a well layer and a barrier layer having a higher band gap than the well layer. For example, the active layer 132 can include an indium gallium nitride (InGaN) layer as a well layer and an aluminum gallium nitride (AlGaN) layer as a barrier layer, but is not limited thereto.

The anode electrode 134 can be disposed (or interposed) between the first semiconductor layer 131 and the solder pattern SDP. The anode electrode 134 can be electrically connected to a corresponding solder pattern SDP of a plurality of solder patterns SDP. For example, the anode electrode 134 can be configured to electrically connect the first semiconductor layer 131 and the first electrode CE1. The anode voltage output from the pixel driving circuit PD can be applied to the first semiconductor layer 131 through the signal line TL, the first electrode CE1, and the anode electrode 134. For example, the anode electrode 134 can be composed of a conductive material capable of eutectic bonding with the solder pattern SDP, but is not limited thereto. For example, the anode electrode 134 can be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or alloys thereof, or the like, but is not limited thereto.

The cathode electrode 135 can be disposed on the second semiconductor layer 133. For example, the cathode electrode 135 can be configured to electrically connect the second semiconductor layer 133 and the second electrode CE2. A cathode voltage output from the pixel driving circuit PD can be applied to the second semiconductor layer 133 through the contact electrode CCE, the second electrode CE2, and the cathode electrode 135. The cathode electrode 135 can be composed of a transparent conductive material so that light emitted from the light emitting device ED can be directed toward an upper portion of the light emitting device ED, but is not limited thereto. For example, the cathode electrode 135 can be composed of a material such as indium tin oxide (ITO), indium zinc oxide (IZO), or indium gallium zinc oxide (IGZO), or the like, but is not limited thereto.

The encapsulation film 136 can be disposed on at least a portion of the first semiconductor layer 131, the active layer 132, the second semiconductor layer 133, the anode electrode 134, and the cathode electrode 135. For example, the encapsulation film 136 can surround at least a portion of the first semiconductor layer 131, the active layer 132, the second semiconductor layer 133, the anode electrode 134, and the cathode electrode 135.

The encapsulation film 136 can protect the first semiconductor layer 131, the active layer 132, and the second semiconductor layer 133. For example, the encapsulation film 136 can be disposed on side surfaces (or lateral surface) of the first semiconductor layer 131, side surfaces (or lateral surface) of the active layer 132, and side surfaces (or lateral surface) of the second semiconductor layer 133.

The encapsulation film 136 can be disposed on at least a portion of the anode electrode 134 and the cathode electrode 135 (for example, an edge portion (or a periphery portion or one side) of the anode electrode 134 and an edge portion (or a periphery portion or one side) of the cathode electrode 135). At least a portion of the anode electrode 134 that is not covered by the encapsulation film 136 can be exposed so that the anode electrode 134 and the solder pattern SDP can be connected. For example, at least a portion of the cathode electrode 135 that is not covered by the encapsulation film 136 can be exposed so that the cathode electrode 135 and the second electrode CE2 can be connected. For example, the encapsulation film 136 can be made of an insulating material such as silicon nitride (SiNx) or silicon oxide (SiOx), but is not limited thereto.

According to another embodiment of the present disclosure, the encapsulation film 136 can have a structure in which a reflective material is dispersed in a resin layer, but is not limited thereto. For example, the encapsulation film 136 can be manufactured as a reflector of various structures, but is not limited thereto. Light emitted from the active layer 132 can be reflected upward by the encapsulation film 136, thereby improving light extraction efficiency. For example, the encapsulation film 136 can be a reflective layer, but is not limited thereto.

According to an embodiment of the present disclosure, the light emitting device ED has been described as having a vertical structure, but is not limited thereto. For example, the light emitting device ED can have a lateral structure or a flip chip structure.

Although the first light emitting device 130 has been described with reference to FIG. 9, the second light emitting device 140 and the third light emitting device 150 can have substantially the same structure as the first light emitting device 130. For example, the second light emitting device 140 and the third light emitting device 150 include substantially the same configuration as the first semiconductor layer 131, the active layer 132, the second semiconductor layer 133, the anode electrode 134, the cathode electrode 135, and the encapsulation film 136 of the first light emitting device 130, and thus, their repetitive descriptions are omitted.

As can be seen in FIGS. 8 and 9, the display apparatus 1000 according to an embodiment of the present disclosure can further include an optical layer (or light diffusion layer) 117a, 117b, and 117c.

The optical layers 117a, 117b, and 117c can be configured to surround a plurality of light emitting devices ED in the display area AA. For example, the optical layers 117a, 117b, and 117c can be configured to cover the plurality of light emitting devices ED in the display area AA. For example, the optical layers 117a and 117b can be configured over the insulating layer 115 to surround side surfaces of each of the plurality of light emitting devices ED and the side surfaces of each of the plurality of banks BNK.

According to an embodiment of the present disclosure, a first optical layer 117a can be disposed to surround the plurality of light emitting devices ED in the display area AA. For example, the first optical layer 117a can be disposed to cover side surfaces of the plurality of light emitting devices ED and side surfaces of the plurality of banks BNK in areas of the plurality of sub-pixels. For example, the first optical layer 117a can cover a portion of the passivation layer 116. For example, the first optical layer 117a can cover the second electrode CE2, the portion of the passivation layer 116, and the area between the plurality of light emitting devices ED. The first optical layer 117a can be disposed or cover between the plurality of light emitting devices ED included in one pixel PX and between the plurality of banks BNK. For example, the first optical layer 117a can extend along a row direction of the display area AA, and the plurality of first optical layers 117a can be spaced apart along a column direction (or the second direction Y) of the display area AA. For example, the first optical layer 117a can be disposed to surround side portions of each of the plurality of light emitting devices ED and the plurality of banks BNK between the insulating layer 115 and the second electrode CE2. For example, the first optical layer 117a can be disposed to surround side portions of each of the light emitting devices ED and the banks BNK between the passivation layer 116 and the second electrode CE2, but is not limited thereto. For example, the first optical layer 117a can be a diffusion layer or a sidewall diffusion layer, but is not limited thereto.

The first optical layer 117a can include an organic insulating material having fine particles 117ap dispersed therein, but is not limited thereto. For example, the first optical layer 117a can be composed of siloxane having fine metal particles 117ap, such as titanium dioxide (TiO₂) particles, dispersed therein, but is not limited thereto. Light from a plurality of light emitting devices ED can be scattered by the fine particles 117ap dispersed in the first optical layer 117a and emitted to an outside of the display panel 100. Accordingly, the first optical layer 117a can improve the extraction efficiency of light emitted from the plurality of light emitting devices ED.

According to an embodiment of the present disclosure, the first optical layer 117a can be disposed at each of the plurality of pixels PX, or can be disposed together at some of the pixels PX which are disposed in the same row of the display area AA, but is not limited thereto. For example, the first optical layer 117a can be disposed at each of the plurality of pixels PX, or one first optical layer 117a can be disposed to share the plurality of pixels PX. As another embodiment of the present disclosure, each of the plurality of sub-pixels can separately include the first optical layer 117a, but is not limited thereto.

According to an embodiment of the present disclosure, a second optical layer 117b can be disposed on the passivation layer 116 in the display area AA. For example, the second optical layer 117b can be disposed to surround side portions of the first optical layer 117a. For example, the second optical layer 117b can be in contact with side surfaces of the first optical layer 117a. For example, the second optical layer 117b can be disposed at an area (or a non-emitting area) between a plurality of pixels PX, but is not limited thereto. For example, the second optical layer 117b can be a diffusion layer, a diffusion layer window, or a window diffusion layer, or the like, but is not limited thereto.

The second optical layer 117b can be composed of an organic insulating material, but is not

limited thereto. The second optical layer 117b can be composed of the same material as the first optical layer 117a, but is not limited thereto. For example, the first optical layer 117a can include fine particles, and the second optical layer 117b may not include the fine particles. For example, the second optical layer 117b can be composed of siloxane, but is not limited thereto.

According to an embodiment of the present disclosure, a thickness of the first optical layer 117a can be smaller than a thickness of the second optical layer 117b, but is not limited thereto. For example, an upper surface of the second optical layer 117b can be formed as a flat surface, and an upper surface of the first optical layer 117a can be formed as a concave curved surface. Accordingly, when viewed in a plan view, an area where the first optical layer 117a is disposed can include a concave portion which is recessed inwardly more than the upper surface of the second optical layer 117b.

According to an embodiment of the present disclosure, the second electrode CE2 can be disposed on the first optical layer 117a and the second optical layer 117b. For example, the second electrode CE2 can be electrically connected to the plurality of contact electrodes CCE through a contact hole of the second optical layer 117b. For example, the second electrode CE2 can be disposed on the plurality of light emitting devices ED. For example, the second electrode CE2 can include a transparent conductive oxide such as indium tin oxide (ITO) or indium zinc oxide (IZO), or the like, but is not limited thereto. For example, the second electrode CE2 can be disposed to be in contact with or directly in contact with the cathode electrode 135. For example, the second electrode CE2 can overlap an entire of the first optical layer 117a and can overlap a portion of the second optical layer 117b. For example, the second electrode CE2 can be electrically connected to the contact electrode CCE through the second optical layer 117b. For example, the second electrode CE2 can be electrically connected to the contact electrode CCE through the contact hole formed in the second optical layer 117b.

The second electrode CE2 can be continuously extended along the row direction (or the first direction X) of the substrate 110. Accordingly, the second electrode CE2 can be commonly connected to the plurality of light emitting devices ED in each of the plurality of pixels PX arranged along the row direction (or the first direction X) of the substrate 110.

According to an embodiment of the present disclosure, the second electrode CE2 can extend continuously over the first optical layer 117a, the second optical layer 117b, and the light emitting device ED. A region where the first optical layer 117a is disposed can include a concave portion which is recessed inwardly more than the upper surface of the second optical layer 117b. Accordingly, a first portion of the second electrode CE2 disposed on the first optical layer 117a can be disposed along the concave portion, and thus can be disposed at a lower position than a second portion of the second electrode CE2 disposed on the second optical layer 117b. For example, the thickness of the first optical layer 117a can progressively decrease from the second optical layer 117b toward a center of the first optical layer 117a for electrical connection (or contact) between each of the first to third light emitting devices 130, 140, and 150 and the second electrode CE2.

The third optical layer 117c can be disposed on the second electrode CE2. The third optical layer 117c can be disposed on the second electrode CE2 so as to overlap with the plurality of light emitting devices ED and the first optical layer 117a. For example, the third optical layer 117c can be disposed so as not to overlap with the second optical layer 117b. Since the third optical layer 117c is disposed on the second electrode CE2 and the plurality of light emitting devices ED, it is possible to improve a stain mura that can occur in some of the plurality of light emitting devices ED. For example, when transferring the plurality of light emitting devices ED onto the substrate 110 of the display panel 100, an area in which an interval (or a spacing) between the plurality of light emitting devices ED is not uniform can occur due to process deviation, or the like. When the interval between the plurality of light emitting devices ED is non-uniform, an emission area of each of the plurality of light emitting devices ED can be non-uniformly formed, and thus, a mura can be visually recognized by the user. Accordingly, since the third optical layer 117c for uniformly diffusing light is additionally configured on an upper portion of the plurality of light emitting devices ED, the light emitted from some of the light emitting devices ED can be reduced or prevented from being visually recognized as the mura. Therefore, since the light emitted from the plurality of light emitting devices ED is uniformly diffused by the third optical layer 117c and extracted to the outside of the display panel 100, uniformity of luminance of the display apparatus can be improved.

The third optical layer 117c can be composed of an organic insulating material having fine particles 117cp dispersed therein, but is not limited thereto. For example, the third optical layer 117c can be composed of siloxane having fine metal particles 117cp such as titanium dioxide (TiO₂) particles dispersed therein, but is not limited thereto. For example, the third optical layer 117c can be composed of the same material as the first optical layer 117a, but is not limited thereto. For example, the third optical layer 117c can be a diffusion layer or a top diffusion layer, but is not limited thereto.

According to an embodiment of the present disclosure, light from a plurality of light emitting devices ED can be scattered by fine particles 117cp dispersed in the third optical layer 117c and emitted to the outside of the display panel 100. The third optical layer 117c can uniformly mix (or diffuse) light emitted from the plurality of light emitting devices ED, thereby further improving uniformity of luminance of the display apparatus. In addition, light extraction efficiency of the display apparatus can be improved by the light scattered by the fine particles 117cp, and thus the display apparatus can be driven at a low-power.

In the display area AA, a black matrix BM can be disposed on the second electrode CE2, the first optical layer 117a, the second optical layer 117b, and the third optical layer 117c.

The black matrix BM can be configured to include a plurality of openings (or light transmitting portions) overlapping each of the plurality of light emitting devices ED. For example, the black matrix BM can be formed (or configured) to cover the remaining display areas except for an area overlapping each of the plurality of light emitting devices ED. For example, the black matrix BM can fill the contact hole of the second optical layer 117b. Since the black matrix BM is configured to cover the display area AA, color mixing of light and external light reflection of the plurality of sub-pixels can be reduced. For example, the black matrix BM can also be disposed within the contact hole where the second electrode CE2 and the contact electrode CCE are connected, and light leakage between the plurality of adjacent sub-pixels can be prevented. For example, the black matrix BM can be made of an opaque material, but is not limited thereto. For example, the black matrix BM can be an organic insulating material to which a black pigment or a black dye is added, but is not limited thereto.

Referring to FIG. 8, the display apparatus 1000 according to an embodiment of the present disclosure can further include a cover layer 118.

The cover layer 118 can be configured to cover the display area AA. The cover layer 118 can be configured to cover the second electrode (or common electrode) CE2 disposed (or configured) in the display area AA. For example, the cover layer 118 can be disposed on the black matrix BM in the display area AA. For example, the black matrix BM can be disposed (or interposed) between the cover layer 118 and the optical layers 117a, 117b, and 117c.

The cover layer 118 can be configured to protect the plurality of light emitting devices ED. For example, the components (or layers) configured between the substrate 110 and the cover layer 118 can be protected by the substrate 110 and the cover layer 118. For example, the cover layer 118 can be configured of an organic insulating material or an inorganic insulating material. For example, the cover layer 118 can be configured of a photo resist, a polyimide, or a photo acryl-based material, or the like, but is not limited thereto. For example, the cover layer 118 can be an overcoating layer, a protection layer, or an insulating layer, or the like, but is are not limited thereto.

According to an embodiment of the present disclosure, the touch panel 200 can be disposed (or configured) on the cover layer 118. The polarizing layer 180 can be disposed on the touch panel 200 by using a first adhesive layer 181. The cover member 120 can be disposed on the polarizing layer 180 by using a second adhesive layer 185.

According to another embodiment of the present disclosure, the touch panel 200 can be disposed (or interposed) between the polarizing layer 180 and the cover member 120, but is not limited thereto. For example, the touch panel 200 can also be connected (or attached) to a rear surface of the cover member 120.

According to another embodiment of the present disclosure, the touch panel 200 can be directly formed (or configured) on the cover layer 118. For example, the touch panel 200 can include a touch electrode layer, and the touch electrode layer can be directly formed (or configured) on an upper surface of the cover layer 118. The polarizing layer 180 can be disposed on the touch electrode layer of the touch panel 200 by using the first adhesive layer 181. The cover member 120 can be disposed on the polarizing layer 180 by using the second adhesive layer 185. For example, each of the first adhesive layer 181 and the second adhesive layer 185 can include an optically cleared adhesive, an optically cleared resin, or a pressure sensitive adhesive, or the like, but is not limited thereto.

According to an embodiment of the present disclosure, a plurality of pad electrodes PE can be disposed on a third insulating layer 115c in the second non-display area NA2. For example, at least a portion of the plurality of pad electrodes PE can be exposed without being covered by the passivation layer 116. For example, the plurality of pad electrodes PE can be electrically connected to the 2-4^{th} connection line 122d through a contact hole of the third insulating layer 115c.

An adhesive film ACF can be disposed on the plurality of pad electrodes PE. The adhesive film ACF can be an adhesive layer in which conductive balls are dispersed on an insulating material, but is not limited thereto. When heat and/or pressure is applied to the adhesive film ACF, the conductive balls can be electrically connected at a portion where the heat and/or pressure is

applied, thereby having conductive characteristics. By disposing the adhesive film ACF between the plurality of pad electrodes PE and the flexible circuit board (or flexible film) 310, the flexible circuit board (or flexible film) 310 can be attached or bonded to the plurality of pad electrodes PE. For example, the adhesive film ACF can be a conductive adhesive material, a conductive adhesive film, or an anisotropic conductive film, but is not limited thereto.

The flexible circuit board 310 can be placed on the adhesive film ACF. The flexible circuit board 310 can be electrically connected to a plurality of pad electrodes PE through the adhesive film ACF. Accordingly, signals output from the flexible circuit board 310 and the printed circuit board 330 can be transmitted to the pixel driving circuit PD in the display area AA through a wiring layer. For example, signals output from the printed circuit board 330 can be transmitted to the pixel driving circuit PD in the display area AA through the flexible circuit board 310, the plurality of pad electrodes PE, the 2-4^{th} connection line 122d, the 2-3^{th} connection line 122c, the 2-2^{th} connection line 122b, and the 2-1^{th} connection line 122a.

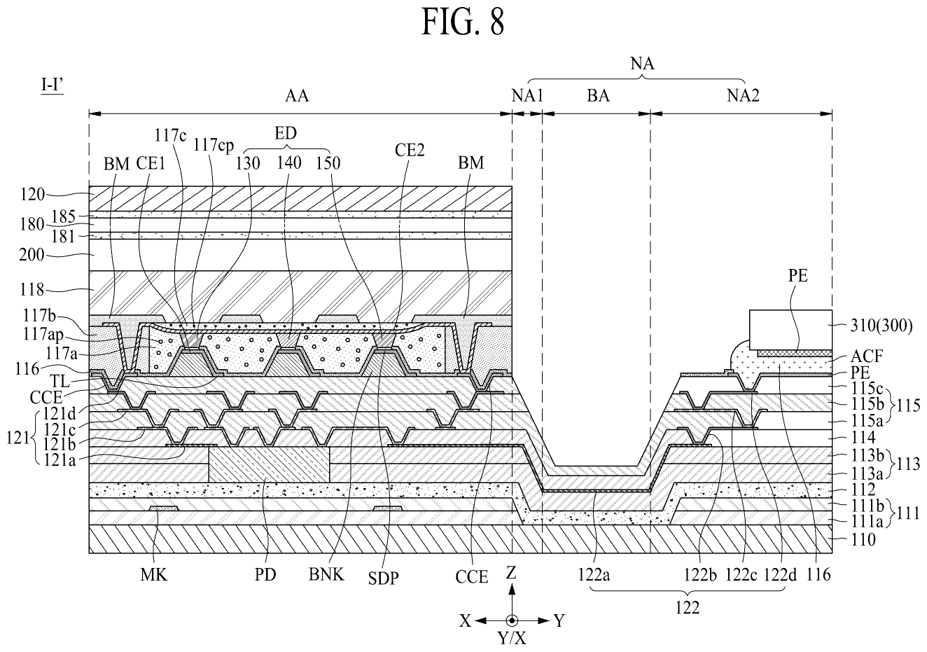

FIG. 10 is a diagram illustrating driving timing of a display panel and a touch panel according to an embodiment of the present disclosure.

Referring to FIG. 10, the display apparatus according to an embodiment of the present disclosure can be driven according to the display period Display_Tn and the touch period Touch_Tn. The display period Display_Tn can be a period for displaying an image on the display panel 100, and the touch period Touch_Tn can be a period for sensing a touch through the touch panel 200. For example, the display period Display_Tn and the touch period Touch_Tn can be the same. That is, the display panel 100 and the touch panel 200 can be driven simultaneously. Accordingly, the display apparatus can display an image on the screen through the display panel 100 while simultaneously sensing a user's touch through the touch panel 200.

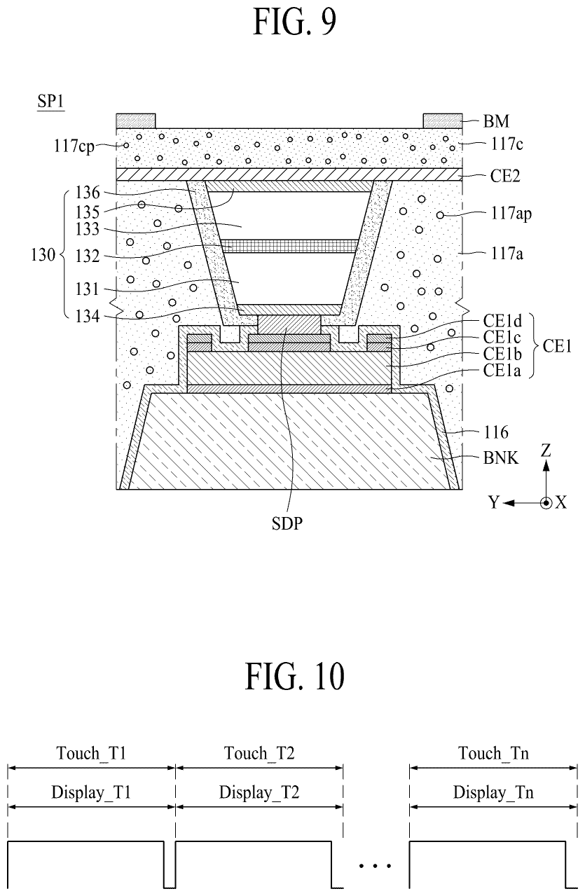

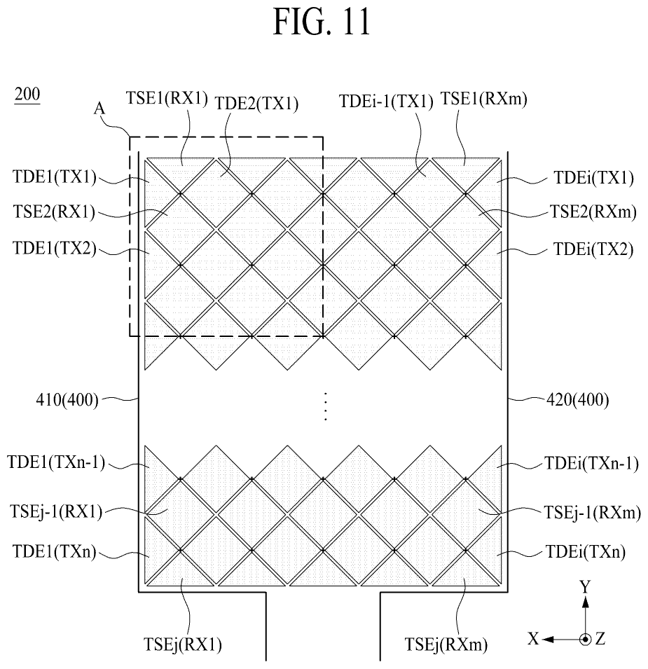

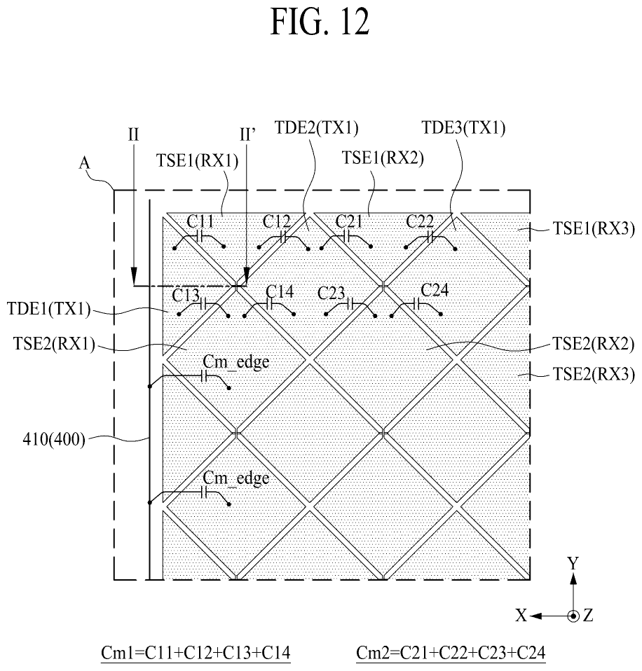

FIG. 11 is a plan view illustrating an electrode structure of a touch panel according to an embodiment of the present disclosure. FIG. 12 is an enlarged view of ‘A’ illustrated in FIG. 11. FIG. 13 is a cross-sectional view taken along line II-II′ illustrated in FIG. 12.

Referring to FIGS. 11 to 13, the touch panel 200 according to an embodiment of the present disclosure can include first to n^{th} touch driving lines TX1 to TXn and first to m^{th} touch sensing lines RX1 to RXm.

The first to n^{th} touch driving lines TX1 to TXn can be a touch driving line for sensing a user's touch. For example, the first to n^{th} touch driving lines TX1 to TXn can be a plurality of first touch lines.

The first to n^{th} touch driving lines TX1 to TXn are parallel to the first direction X and can be spaced apart from each other along the second direction Y. For example, each of the first to n^{th} touch driving lines TX1 to TXn can be disposed (or configured) to overlap one row (or a horizontal line) of the display panel or to overlap one or more second electrodes CE2.

Each of the first to n^{th} touch driving lines TX1 to TXn according to an embodiment can include first to i^{th} (i is a natural number of 4 or more) touch driving electrodes TDE1 to TDEi and a plurality of bridge electrodes BE.

The first touch driving electrode TDE1 can be disposed on one side portion (or one end portion) of each of the first to n^{th} touch driving lines TX1 to TXn, and the i^{th} touch driving electrode TDEi can be disposed on the other side portion (or the other end portion) of each of the first to n^{th} touch driving lines TX1 to TXn. The first touch driving electrode TDE1 can be disposed (or configured) on a first edge portion (for example, a left periphery portion) of the touch panel 200, and the i^{th} touch driving electrode TDEi can be disposed (or configured) on a second edge portion (for example, a right periphery portion) opposite to the first edge portion of the touch panel 200. The second to (i−1)^{th} touch driving electrodes TDE2 to TDEi-1 can be disposed (or configured) to have a predetermined interval between the first touch driving electrode TDE1 and the i^{th} touch driving electrode TDEi along the first direction X. Accordingly, each of the first and i^{th} touch driving electrodes TDE1 and TDEi can be an edge driving electrode, and each of the second to (i−1)^{th} touch driving electrodes TDE2 to TDEi-1 can be an intermediate driving electrode.

Some of the first to i^{th} touch driving electrodes TDE1 to TDEi can have different sizes depending on an electrode arrangement structure (or an electrode arrangement position). For example, each of the first and i^{th} touch driving electrodes TDE1 and TDEi can have a size smaller than that of each of the second to (i−1)^{th} touch driving electrodes TDE2 to TDEi-1.

Some of the first to i^{th} touch driving electrodes TDE1 to TDEi can have different shapes and different sizes depending on the electrode arrangement structure (or the electrode arrangement position). For example, each of the first and i^{th} touch driving electrodes TDE1 and TDEi can have a different shape from that of the second to (i−1)^{th} touch driving electrodes TDE2 to TDEi-1, and can have a size smaller than that of each of the second to (i−1)^{th} touch driving electrodes TDE2 to TDEi-1.

According to an embodiment, each of the second to (i−1)^{th} touch driving electrodes TDE2 to TDEi-1 can have a rectangular shape or a rhombus shape. Each of the first and i^{th} touch driving electrodes TDE1 and TDEi can have a triangular shape, but is not limited thereto. For example, each of the first and i^{th} touch driving electrodes TDE1 and TDEi can have a triangular shape having a size of half that of each of the second to (i−1)^{th} touch driving electrodes TDE2 to TDEi-1, but is not limited thereto.

According to another embodiment, when each of the first and i^{th} touch driving electrodes TDE1 and TDEi has a smaller size than each of the second to (i−1)^{th} touch driving electrodes TDE2 to TDEi-1, each of the first and i^{th} touch driving electrodes TDE1 and TDEi can have the same shape or a different shape as each of the second to (i−1)^{th} touch driving electrodes TDE2 to TDEi-1. For example, each of the second to (i−1)^{th} touch driving electrodes TDE2 to TDEi-1 has a rectangular shape or a rhombus shape, and each of the first and i^{th} touch driving electrodes TDE1 and TDEi can have a triangular shape or a rectangular shape (or a pentagonal shape) having a smaller size than each of the second to (i−1)^{th} touch driving electrodes TDE2 to TDEi-1.

The plurality of bridge electrodes BE can be disposed (or configured) to connect the first to i^{th} touch driving electrodes TDE1 to TDEi, or can be configured to connect between the first to ith touch driving electrodes TDE1 to TDEi. The plurality of bridge electrodes BE can be disposed (or configured) on different layers from the first to i^{th} touch driving electrodes TDE1 to TDEi. The plurality of bridge electrodes BE can be disposed (or configured) to be electrically connected to two adjacent touch driving electrodes along the first direction X of the first to i^{th} touch driving electrodes TDE1 to TDEi. For example, the touch driving electrodes TDE1 to TDEi and the bridge electrode BE can be alternately and repeatedly disposed (or configured) along the first direction X to be electrically connected to each other. Accordingly, the first to i^{th} touch driving electrodes TDE1 to TDEi are electrically connected to each other through the plurality of bridge electrodes BE, and thus, the first to i^{th} touch driving electrodes TDE1 to TDEi and the plurality of bridge electrodes BE can configure one touch driving line TX1 to TXn.

The first to m^{th} touch sensing lines RX1 to RXm can be touch sensing lines for sensing a user's touch. For example, the first to m^{th} touch sensing lines RX1 to RXm can be a plurality of second touch lines.

Each of the first to m^{th} touch sensing lines RX1 to RXm can be configured to form a mutual capacitance with the adjacent touch driving lines of the first to n^{th} touch driving lines TX1 to TXn. The first to m^{th} touch sensing lines RX1 to RXm can be parallel to the second direction Y and can be spaced apart from each other along the first direction X. For example, each of the first to m^{th} touch sensing lines RX1 to RXm can be disposed (or configured) to cross the first to n^{th} touch driving lines TX1 to TXn. For example, the first touch sensing line RX1 can be disposed (or configured) at a first edge portion of the touch panel 200, and the m^{th} touch sensing line RXm can be disposed (or configured) at a second edge portion of the touch panel 200. For example, the first and m^{th} touch sensing lines RX1 and RXm can be edge sensing lines, and the second to (m−1)^{th} touch sensing lines RX2 to RXm-1 can be intermediate sensing lines.

Each of the first to m^{th} touch sensing lines RX1 to RXm according to an embodiment can include first to j^{th} (where j is a natural number of 4 or more) touch sensing electrodes TSE1 to TSEj and a plurality of electrode connection lines ECL.

The first touch sensing electrode TSE1 can be disposed at one side portion (or one end portion) of each of the first to m^{th} touch sensing lines RX1 to RXm, and the j^{th} touch sensing electrode TSEj can be disposed at the other side portion (or the other end portion) of each of the first to m^{th} touch sensing lines RX1 to RXm. The first touch sensing electrode TSE1 can be disposed (or configured) at a third edge portion (for example, an upper periphery portion) of the touch panel 200, and the j^{th} touch sensing electrode TSEj can be disposed (or configured) at a fourth edge portion (for example, a lower periphery portion) opposite to the third periphery portion of the touch panel 200. The second to (j−1)^{th} touch sensing electrodes TSE2 to TSEj-1 can be disposed (or configured) to have a predetermined interval between the first touch sensing electrode TSE1 and the j^{th} touch sensing electrode TSEj along the second direction Y. Accordingly, each of the first and j^{th} touch sensing electrodes TSE1 and TSEj can be an edge sensing electrode, and each of the second to (j−1)^{th} touch sensing electrodes TSE2 to TSEj-1 can be an intermediate sensing electrode.

Some of the first to j^{th} touch sensing electrodes TSE1 to TSEj can have different sizes depending on an electrode arrangement structure (or an electrode arrangement position). For example, each of the first and j^{th} touch sensing electrodes TSE1 and TSEj can have a smaller size than that of each of the second to (j−1)^{th} touch sensing electrodes TSE2 to TSEj-1.

Some of the first to j^{th} touch sensing electrodes TSE1 to TSEj can have different shapes and different sizes depending on the electrode arrangement structure (or the electrode arrangement position). Each of the first and j^{th} touch sensing electrodes TSE1 and TSEj can have a shape different from that of the second to (j−1)^{th} touch sensing electrodes TSE2 to TSEj-1, and can have a size smaller than that of each of the second to (j−1)^{th} touch sensing electrodes TSE2 to TSEj-1.

According to an embodiment, each of the second to (j−1)^{th} touch sensing electrodes TSE2 to TSEj-1 can have a rectangular shape or a rhombus shape. Each of the first and j^{th} touch sensing electrodes TSE1 and TSEj can have a triangular shape, but is not limited thereto. For example, each of the first and j^{th} touch sensing electrodes TSE1 and TSEj can have a triangular shape having a size of half of each of the second to (j−1)^{th} touch sensing electrodes TSE2 to TSEj-1, but is not limited thereto.

According to another embodiment, when each of the first and j^{th} touch sensing electrodes TSE1 and TSEj has a smaller size than that of each of the second to (j−1)^{th} touch sensing electrodes TSE2 to TSEj-1, each of the first and j^{th} touch sensing electrodes TSE1 and TSEj can have the same shape or a different shape as each of the second to (j−1)^{th} touch sensing electrodes TSE2 to TSEj-1. For example, each of the second to (j−1)^{th} touch sensing electrodes TSE2 to TSEj-1 can have a rectangular shape or a rhombus shape, and each of the first and j^{th} touch sensing electrodes TSE1 and TSEj can have a triangular shape or a rectangular shape (or a pentagonal shape) having a smaller size than that of each of the second to (j−1)^{th} touch sensing electrodes TSE2 to TSEj-1.

The first to j^{th} touch sensing electrodes TSE1 to TSEj can be disposed (or configured) between the first to i^{th} touch driving electrodes TDE1 to TDEi. Accordingly, the touch driving electrodes TDE1 to TDEi and the touch sensing electrodes TSE1 to TSEj can be alternately disposed (or configured) along each of the first and second directions X and Y.

The plurality of electrode connection lines ECL can be disposed (or configured) to connect the first to j^{th} touch sensing electrodes TSE1 to TSEj, or can be configured to connect between the first to j^{th} touch sensing electrodes TSE1 to TSEj. The plurality of electrode connection lines ECL can be disposed (or configured) on the same layer as the first to j^{th} touch sensing electrodes TSE1 to TSEj. The plurality of electrode connection lines ECL can be disposed (or configured) to be electrically connected to two touch sensing electrodes adjacent to each other along the second direction Y of the first to j^{th} touch sensing electrodes TSE1 to TSEj. For example, the j touch sensing electrodes TSE1 to TSEj and the j−1 electrode connection lines ECL can be alternately and repeatedly disposed (or configured) along the second direction Y to be electrically connected to each other. Accordingly, the first to j^{th} touch sensing electrodes TSE1 to TSEj are electrically connected to each other through the plurality of electrode connection lines ECL, and thus the first to j^{th} touch sensing electrodes TSE1 to TSEj and the plurality of electrode connection lines ECL can configure one touch sensing line RX1 to RXm. For example, each of the plurality of electrode connection lines ECL can be an extension portion (or an extension line) or a protrusion portion (or a protrusion line) of the first to j^{th} touch sensing electrodes TSE1 to TSEj.

Referring to FIG. 13, the touch panel 200 according to an embodiment of the present disclosure can include a touch electrode layer 210 and a passivation layer 230.

The touch electrode layer 210 can be directly formed (or configured) on the cover layer 118 of the display panel, but is not limited thereto. For example, a touch buffer layer can be disposed (or interposed) between the touch electrode layer 210 and the cover layer 118. In this case, the touch electrode layer 210 can be directly formed (or configured) on the touch buffer layer covering the cover layer 118.

The touch panel 200 or the touch electrode layer 210 according to an embodiment can include a first touch electrode layer, a touch insulating layer 213, and a second touch electrode layer.

The first touch electrode layer can be formed (or configured) on the cover layer 118 (or touch buffer layer). The touch insulating layer 213 can be formed (or configured) to cover the first touch electrode layer. The touch insulating layer 213 can be made of an inorganic insulating material or an organic insulating material. The second touch electrode layer can be formed (or configured) on the touch insulating layer 213.

The first to i^{th} touch driving electrodes TDE1 to TDEi of each of the first to n^{th} touch driving lines TX1 to TXn can be formed (or configured) on/at any one of the first and second touch electrode layers. The plurality of bridge electrodes BE of each of the first to n^{th} touch driving lines TX1 to TXn can be formed (or configured) on a different layer from the first to i^{th} touch driving electrodes TDE1 to TDEi of the first touch electrode layer and second touch electrode layer. For example, each of the plurality of bridge electrodes BE of each of the first to n^{th} touch driving lines TX1 to TXn can be configured to be electrically connected to two adjacent touch driving electrodes of the first to i^{th} touch driving electrodes TDE1 to TDEi through a via hole VH provided in the touch insulating layer 213.

The first to j^{th} touch sensing electrodes TSE1 to TSEj and the plurality of electrode connection lines ECL of each of the first to m^{th} touch sensing lines RX1 to RXm can be formed (or configured) on the same layer as the first to i^{th} touch driving electrodes TDE1 to TDEi.

According to an embodiment, the plurality of bridge electrodes BE of each of the first to n^{th} touch driving lines TX1 to TXn can be formed (or configured) in the first touch electrode layer, and the first to i^{th} touch driving electrodes TDE1 to TDEi of each of the first to n^{th} touch driving lines TX1 to TXn and the first to m^{th} touch sensing lines RX1 to RXm can be formed (or configured) in the second touch electrode layer, but is not limited thereto. For example, the plurality of bridge electrodes BE of each of the first to n^{th} touch driving lines TX1 to TXn can be formed (or configured) in the second touch electrode layer, and the first to ith touch driving electrodes TDE1 to TDEi of each of the first to nth touch driving lines TX1 to TXn and the first to mth touch sensing lines RX1 to RXm can be formed (or configured) in the first touch electrode layer.

According to an embodiment, the first to n^{th} touch driving lines TX1 to TXn and the first to m^{th} touch sensing lines RX1 to RXm can be composed of a transparent conductive material or the same material as the plurality of second electrodes CE2.

The passivation layer 230 can be formed (or configured) to cover the touch electrode layer 210. The passivation layer 230 can be made of an organic insulating material. The passivation layer 230 can be a touch protection layer. The passivation layer 230 can be connected (or coupled) to a rear surface of the polarizing layer 180 by the first adhesive layer 181. For example, the polarizing layer 180 can be attached to an upper surface of the passivation layer 230 by using the first adhesive layer 181.

According to another embodiment of the present disclosure, each of the first to n^{th} touch driving lines TX1 to TXn and the first to m^{th} touch sensing lines RX1 to RXm can include a mesh structure. In order to minimize (or prevent) a decrease in light transmittance caused by the touch panel 200 (or the touch electrode layer 210), each of the first to n^{th} touch driving lines TX1 to TXn and the first to m^{th} touch sensing lines RX1 to RXm can include a mesh structure having a mesh line ML.

The mesh line ML can be formed (or configured) to have a constant (or fine) line width W1. The mesh line ML overlaps the black matrix BM, and can include a line width W1 smaller than that of the line width W2 of the black matrix BM. For example, some of the mesh lines ML overlapping the black matrix BMa disposed between the plurality of light emitting devices 130, 140, and 150 can have a line width W1 smaller than that of the line width W2 of the black matrix BMa. Accordingly, since some of the mesh lines ML do not overlap openings overlapping each of the plurality of light emitting devices ED (or the plurality of first to third light emitting devices 130, 140, and 150), a decrease in light transmittance caused by the mesh line ML (or the touch electrode layer 210) can be minimized (or prevented).

According to an embodiment, the mesh line ML can include a plurality of first mesh lines parallel to the first direction X and a plurality of second mesh lines parallel to the second direction Y and intersecting the first mesh line. The plurality of first mesh lines and the plurality of second mesh lines can be formed (or configured) on the same layer. A line width W1 of each of the plurality of first mesh lines and the plurality of second mesh lines can be smaller than that of the line width W2 of the black matrix BMa.

The mesh line ML having the line width W1 smaller than that of the line width W2 of the black matrix BMa does not affect light transmittance, and thus, can be formed of a metal material having high conductivity. For example, the mesh line ML can be formed of gold (Au), silver (Ag), aluminum (Al), molybdenum (Mo), chromium (Cr), titanium (Ti), nickel (Ni), neodymium (Nd), copper (Cu), an alloy of silver (Ag) and magnesium (Mg), or an alloy thereof, but is not limited thereto.

In the description referring to FIG. 13, the touch electrode layer 210 including the first to n^{th} touch driving lines TX1 to TXn and the first to m^{th} touch sensing lines RX1 to RXm is directly formed (or configured) on the upper surface of the cover layer 118, but is not limited thereto. For example, the touch panel 200 according to another embodiment of the present disclosure can include a first transparent film, a touch electrode layer 210 including the first to n^{th} touch driving lines TX1 to TXn and the first to mth touch sensing lines RX1 to RXm which are formed (or configured) on the first transparent film, and a second transparent film covering the touch electrode layer 210. The touch panel 200 including the first transparent film, the touch electrode layer 210, and the second transparent film can be attached to the upper surface of the cover layer 118 by using an adhesive layer. For example, the first transparent film of the touch panel 200 can be attached to the cover layer 118 by the adhesive layer. The polarizing layer 180 can be attached to the first transparent film of the touch panel 200 by using the first adhesive layer 181.

Referring to FIGS. 11 to 13, in the display apparatus according to an embodiment of the present disclosure, the touch auxiliary line 400 can be formed (or configured) on the touch panel 200 (or the touch electrode layer 210). The touch auxiliary line 400 can be spaced apart from ends of each of the first to n^{th} touch driving lines TX1 to TXn, and can be configured to form a mutual capacitance Cm_edge with at least a part of the first to m^{th} touch sensing lines RX1 to RXm. The touch auxiliary line 400 can be formed (or configured) on the touch panel 200 (or the touch electrode layer 210) in parallel with the first to m^{th} touch sensing lines RX1 to RXm.

The touch auxiliary line 400 can be disposed (or configured) to increase a total capacitance of the first and m^{th} touch sensing lines RX1 and RXm disposed (or configured) at the edge portion of the screen among the first to m^{th} touch sensing lines RX1 to RXm. Accordingly, as the capacitance between each of the first and m^{th} touch sensing lines RX1 and RXm which are disposed (or configured) at the edge portion of the screen increases (or is reinforced), the touch sensitivity (or touch performance) at the edge portion of the screen can be improved, and non-uniformity of touch sensitivity (or touch performance) can be prevented or minimized.

The touch auxiliary line 400 can be formed (or configured) on the touch panel 200 (or the touch electrode layer 210) so as to be spaced apart from an end TXe of each of the first and i^{th} touch driving electrodes TDE1 and TDEi which configure (or form) each of the first to nth touch driving lines TX1 to TXn. For example, the touch auxiliary line 400 can be disposed (or configured) on the same layer as the first and m^{th} touch sensing lines RX1 and RXm or can be configured on the same layer as the plurality of bridge electrodes BE.

The touch auxiliary line 400 can be formed (or configured) to compensate for a deviation between the capacitance (or first capacitance) Cm1 of the edge sensing line (or edge sensing electrode) RX1 or RXm and the capacitance (or second capacitance) Cm2 of the intermediate sensing line (or intermediate sensing electrode) RX2 to RXm-1. For example, the touch auxiliary line 400 can form a mutual capacitance Cm_edge with the edge sensing lines RX1 and RXm. For convenience of description, hereinafter, the mutual capacitance (or auxiliary capacitance) formed between the touch auxiliary line 400 and the edge sensing lines RX1 and RXm can be referred to as edge capacitance Cm_edge.

The edge capacitance Cm_edge formed between the touch auxiliary line 400 and the edge sensing lines RX1 and RXm can be formed in parallel with the first capacitance Cm1 to increase the first capacitance Cm1. For example, the touch auxiliary line 400 can be formed (or configured) such that the edge capacitance Cm_edge corresponds to the deviation between the first capacitance Cm1 and the second capacitance Cm2.

For example, in the first to n^{th} touch driving lines TX1 to TXn, since the size of the first touch driving electrode TDE1 is different from the size of the second touch driving electrode TDE2, the first capacitance Cm1 formed in the first touch sensing line RX1 (or the m^{th} touch sensing line RXm) can be different from the second capacitance Cm2 formed in the second touch sensing line RX2.

For example, the first capacitance Cm1 formed in the first touch sensing line RX1 can be a sum (Cm1=C11+C12+C13+C14) of a 1-1^{th} capacitance C11 between the first touch sensing electrode TSE1 and the first touch driving electrode TDE1, a 1-2^{th} capacitance C12 between the first touch sensing electrode TSE1 and the second touch driving electrode TDE2, a 1-3^{th} capacitance C13 between the second touch sensing electrode TSE2 and the first touch driving electrode TDE1, and a 1-4^{th} capacitance C14 between the second touch sensing electrode TSE2 and the second touch driving electrode TDE2.

For example, the second capacitance Cm2 formed in the second touch sensing line RX2 can be a sum (Cm2=C21+C22+C23+C24) of a 2-1^{th} capacitance C21 between the first touch sensing electrode TSE1 and the second touch driving electrode TDE2, a 2-2^{th} capacitance C22 between the first touch sensing electrode TSE1 and the third touch driving electrode TDE3, a 2-3^{th} capacitance C23 between the second touch sensing electrode TSE2 and the second touch driving electrode TDE2, and a 2-4^{th} capacitance C24 between the second touch sensing electrode TSE2 and the third touch driving electrode TDE3.

For example, when the touch auxiliary line 400 is not disposed, the first touch driving electrode TDE1 having a triangular shape (or a rectangular shape) has a smaller size than that of each of the second and third touch driving electrodes TDE2 and TDE3 having a rhombus shape (or a rectangular shape), and thus, the first capacitance Cm1 can be smaller than the second capacitance Cm2.

As in the embodiment of the present disclosure, when the touch auxiliary line 400 is disposed, the edge capacitance Cm_edge is formed in parallel with the first capacitance Cm1 between the touch auxiliary line 400 and the first touch sensing line RX1 (or the m^{th} touch sensing line RXm). Accordingly, since the edge capacitance Cm_edge formed by the touch auxiliary line 400 is added to the first capacitance Cm1, the total capacitance Cm1+Cm_edge formed in the first touch sensing line RX1 can be the same as or similar to the second capacitance Cm2 formed in the second touch sensing line RX2.

The touch auxiliary line 400 according to an embodiment of the present disclosure can include a first touch auxiliary line 410 and a second touch auxiliary line 420.

The first touch auxiliary line 410 can be disposed (or configured) at the first edge portion of the touch panel 200 to be adjacent or parallel to the first touch driving electrode TDE1 of each of the first to n^{th} touch driving lines TX1 to TXn. For example, the first touch auxiliary line 410 can

be disposed (or configured) at the first edge portion of the touch panel 200 to be parallel to the second direction Y. The first touch auxiliary line 410 can be adjacent or parallel to each of the first touch driving electrodes TDE1 which configure each of the first to n^{th} touch driving lines TX1 to TXn.

The first touch auxiliary line 410 can be configured to form edge capacitance Cm_edge with the first touch sensing line RX1. For example, the first touch auxiliary line 410 can form edge capacitance Cm_edge with each of the first to j^{th} touch sensing electrodes TSE1 to TSEj of the first touch sensing line RX1. For example, the first touch auxiliary line 410 can form edge capacitance Cm_edge in common with the first to j^{th} touch sensing electrodes TSE1 to TSEj of the first touch sensing line RX1. Accordingly, since edge capacitance Cm_edge is formed between the first touch auxiliary line 410 and the first touch sensing line RX1, and thus, the mutual capacitance between the first touch sensing line RX1 and the first to n^{th} touch driving lines TX1 to TXn can be increased. Therefore, the first touch auxiliary line 410 can improve touch sensitivity (or touch performance) at the first edge portion of the touch panel 200.

The second touch auxiliary line 420 can be configured to form edge capacitance Cm_edge with the m^{th} touch sensing line RXm. The second touch auxiliary line 420 can be configured to be adjacent to the i^{th} touch driving electrode TDEi of each of the first to n^{th} touch driving lines TX1 to TXn. For example, the second touch auxiliary line 420 can form edge capacitance Cm_edge with each of the first to j^{th} touch sensing electrodes TSE1 to TSEj of the m^{th} touch sensing line RXm. For example, the second touch auxiliary line 420 can form edge capacitance Cm_edge in common with the first to j^{th} touch sensing electrodes TSE1 to TSEj of the m^{th} touch sensing line RXm. Accordingly, since edge capacitance Cm_edge is formed between the second touch auxiliary line 420 and the m^{th} touch sensing line RXm, and thus, the mutual capacitance between the m^{th} touch sensing line RXm and the first to n^{th} touch driving lines TX1 to TXn can be increased. Therefore, the second touch auxiliary line 420 can improve touch sensitivity (or touch performance) at the second edge portion of the touch panel 200.

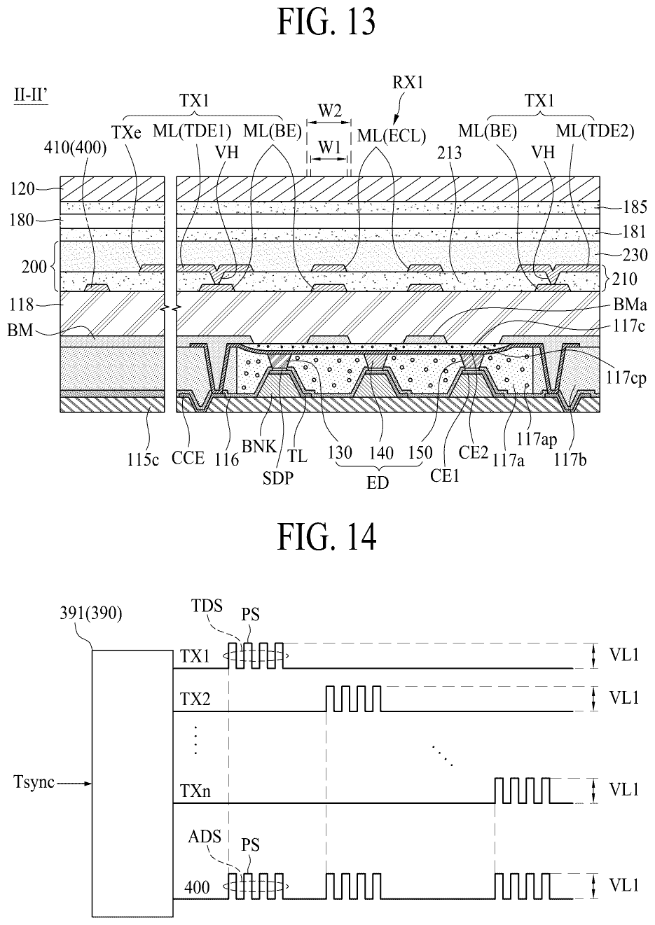

FIG. 14 is a diagram illustrating an output signal of a touch driving circuit according to an embodiment of the present disclosure.

Referring to FIGS. 11, 12, and 14, the touch driving circuit 390 according to an embodiment of the present disclosure can be electrically connected to the first to n^{th} touch driving lines TX1 to TXn, the first to m^{th} touch sensing lines RX1 to RXm, and the touch auxiliary line 400 of the touch panel 200. The touch driving circuit 390 can be configured to supply a touch driving signal TDS to each of the first to n^{th} touch driving lines TX1 to TXn based on the touch synchronization signal Tsync, and supply an auxiliary driving signal ADS synchronized with the touch driving signal TDS to the touch auxiliary line 400.

The touch driving circuit 390 according to an embodiment of the present disclosure can include a touch driving part 391.

The touch driving part 391 can be configured to sequentially supply the touch driving signal TDS to each of the first to n^{th} touch driving lines TX1 to TXn based on the touch synchronization signal Tsync, and to supply the auxiliary driving signal ADS synchronized with the touch driving signal TDS to the touch auxiliary line 400. For example, the touch driving part 391 can generate the touch driving signal TDS and the auxiliary driving signal ADS having one or more pulse signals PS through the pulse width modulation method, and can sequentially supply the touch driving signal TDS to each of the first to n^{th} touch driving lines TX1 to TXn based on the touch synchronization signal Tsync, and can repeatedly supply the auxiliary driving signal ADS synchronized with each of the touch driving signals TDS sequentially supplied to each of the first to n^{th} touch driving lines TX1 to TXn to the touch auxiliary line 400.

Each of the touch driving signal TDS and the auxiliary driving signal ADS can include the one or more pulse signals PS having the same phase and the same pulse width. Each of the touch driving signal TDS and the auxiliary driving signal ADS according to an embodiment can include the one or more pulse signals PS having the same phase, the same voltage level VL1 (or the same amplitude), and the same pulse width, but are not limited thereto. For example, a phase, a voltage level VL1, (or a voltage amplitude), and a pulse width of each of the one or more pulse signals PS of the touch driving signal TDS and the one or more pulse signals PS of the auxiliary driving signal ADS can be the same as each other, but are not limited thereto. For example, when the total capacitance Cm1+Cm_edge formed on the edge sensing lines RX1 and RXm is the same as or similar to the second capacitance Cm2 formed on the intermediate sensing lines RX2 to RXm-1, the touch driving circuit 390 (or the touch driving part 391) can be configured to simultaneously output the one or more pulse signals PS of the touch driving signal TDS and the one or more pulse signals PS of the auxiliary driving signal ADS having the same phase, the voltage level VL1 (or voltage amplitude), and the pulse width, respectively.

The touch driving circuit 390 according to an embodiment of the present disclosure can be embedded (or integrated) in the driving integrated circuit 311 or implemented (or configured) inside the driving integrated circuit 311. For example, the touch driving part 391 can be embedded (or integrated) in the power management integrated circuit 370 or implemented (or configured) inside the power management integrated circuit 370.

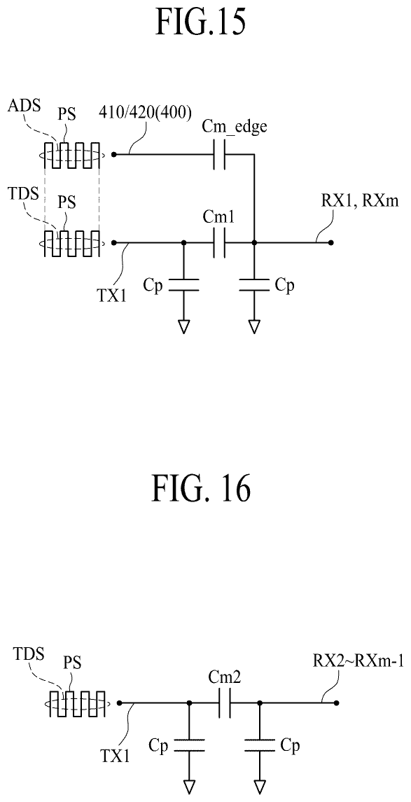

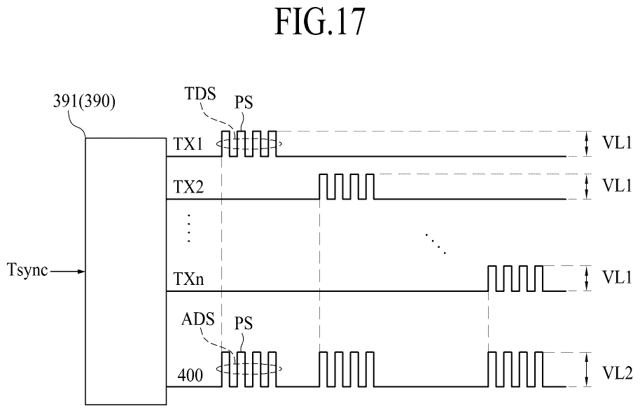

FIG. 15 is a diagram illustrating capacitance formed on an edge sensing line of the touch panel illustrated in FIGS. 11 and 12. FIG. 16 is a diagram illustrating capacitance formed on an intermediate sensing line of the touch panel illustrated in FIGS. 11 and 12.

Referring to FIGS. 15 and 16, when the touch driving signal TDS is applied to the touch driving lines TX1 to TXn and the auxiliary driving signal ADS synchronized with the touch driving signal TDS is applied to the touch auxiliary line 400, the edge capacitance Cm_edge can be formed between the edge sensing lines RX1 and RXm and the touch auxiliary line 400, and the first capacitance Cm1 can be formed between the touch driving lines TX1 to TXn and the edge sensing lines RX1 and RXm. Simultaneously, the second capacitance Cm2 can be formed between the touch driving lines TX1 to TXn and the intermediate sensing lines RX2 to RXm-1. Accordingly, the total capacitance Cm1+Cm_edge formed on the edge sensing lines RX1 and RXm by the edge capacitance Cm_edge formed due to the touch auxiliary line 400 can be the same as or similar to the second capacitance Cm2 formed on the intermediate sensing lines RX2 to RXm-1. For example, the total capacitance Cm1+Cm_edge formed in each of the first and m^{th} touch sensing lines RX1 and RXm by the edge capacitance Cm_edge formed due to the touch auxiliary line 400 can be the same as or similar to the second capacitance Cm2 formed in each of the second to (m−1)th touch sensing lines RX2 to RXm-1.

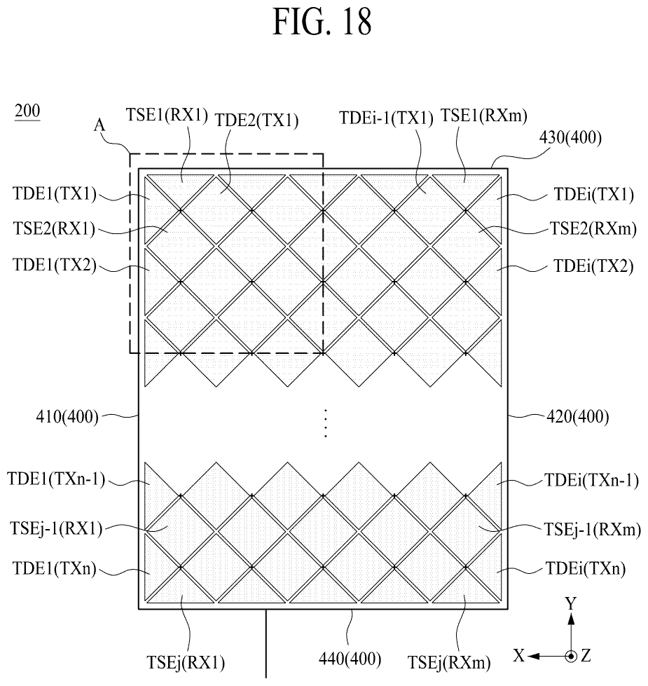

FIG. 17 is a diagram illustrating an output signal of a touch driving circuit according to another embodiment of the present disclosure. For example, FIG. 17 illustrates an embodiment implemented by modifying an auxiliary driving signal of output signals of the touch driving circuit described above with reference to FIGS. 11, 12, and 14. In the following description, therefore, the auxiliary driving signal will be only described, and their repetitive descriptions are omitted or will be briefly given. Therefore, descriptions of FIGS. 11, 12, and 14 can be included in descriptions to FIG. 17.

Referring to FIGS. 11, 12, and 17, according to another embodiment of the present disclosure, each of the touch driving signal TDS and the auxiliary driving signal ADS can include one or more pulse signals PS having the same phase and the same pulse width. The one or more pulse signals PS of the touch driving signal TDS and one or more pulse signals PS of the auxiliary driving signal ADS can have different voltage levels (or voltage amplitudes). For example, the voltage level VL2 (or voltage amplitude) of the one or more pulse signals PS of the auxiliary driving signal ADS can be higher than that of the voltage level VL1 (or voltage amplitude) of the one or more pulse signals PS of the touch driving signal TDS. For example, when the total capacitance Cm1+Cm_edge formed in the edge sensing lines RX1 and RXm is smaller than that the second capacitance Cm2 formed in the intermediate sensing lines RX2 to RXm-1, the touch driving circuit 390 (or the touch driving part 391) can be configured to simultaneously output the one or more pulse signals PS of the touch driving signal TDS and the one or more pulse signals PS of the auxiliary driving signal ADS having the same phase and pulse width and different voltage levels (or voltage amplitudes) VL1 and VL2.

According to another embodiment of the present disclosure, the total capacitance Cm1+Cm_edge formed in the edge sensing lines RX1 and RXm by the edge capacitance Cm_edge formed due to the voltage level VL2 (or voltage amplitude) of the touch auxiliary line 400 and the auxiliary driving signal ADS can be the same as or similar to the second capacitance Cm2 formed in the intermediate sensing lines RX2 to RXm-1. For example, the total capacitance Cm1+Cm_edge formed in each of the first and m^{th} touch sensing lines RX1 and RXm by the edge capacitance Cm_edge formed due to the voltage level VL2 (or voltage amplitude) of the touch auxiliary line 400 and the auxiliary driving signal ADS can be the same as or similar to the second capacitance Cm2 formed in each of the second to (m−1)^{th} touch sensing lines RX2 to RXm-1.

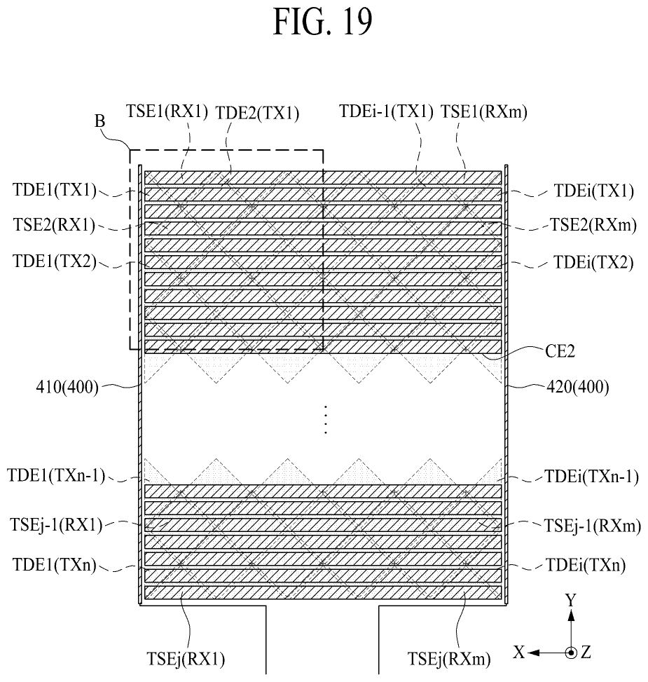

FIG. 18 is a diagram illustrating a touch panel of a display apparatus according to another embodiment of the present disclosure. For example, FIG. 18 illustrates an embodiment implemented by modifying a touch auxiliary line described above with reference to FIGS. 11 to 17. In the following description, therefore, the touch auxiliary line will be only described, and their repetitive descriptions are omitted or will be briefly given. Therefore, descriptions of FIGS. 11 to 17 can be included in descriptions to FIG. 18.

Referring to FIG. 18, in a display apparatus according to another embodiment of the present disclosure, the touch auxiliary line 400 can be spaced apart from the ends of each of the first to n^{th} touch driving lines TX1 to TXn and the ends of each of the first to m^{th} touch sensing lines RX1 to RXm and form a mutual capacitance with each of the first to m^{th} touch sensing lines RX1 to RXm.

The touch auxiliary line 400 can be spaced apart from the ends of each of the first and i^{th} touch driving electrodes TDE1 and TDEi of each of the first to n^{th} touch driving lines TX1 to TXn, and can be spaced apart from the ends of each of the first and j^{th} touch sensing electrodes TSE1 and TSEj of each of the first to m^{th} touch sensing lines RX1 to RXm. Accordingly, the touch auxiliary line 400 can be configured to form the mutual capacitance with each of the first to j^{th} touch sensing electrodes TSE1 to TSEj of each of the first and m^{th} touch sensing lines RX1 to RXm, and can be configured to form the mutual capacitance with each of the first and j^{th} touch sensing electrodes TSE1 and TSEj of each of the first to m^{th} touch sensing lines RX1 to RXm. For example, the touch auxiliary line 400 described above with reference to FIGS. 11 to 17 is configured to additionally form the mutual capacitance with each of the first and j^{th} touch sensing electrodes TSE1 and TSEj of each of the first to m^{th} touch sensing lines RX1 to RXm.

The touch auxiliary line 400 can include a ring shape disposed along an edge portion of the touch panel 200 or configured at an edge portion of the touch panel 200. For example, the touch auxiliary line 400 can include a ring shape overlapping the edge portion of the touch panel 200. For example, the touch auxiliary line 400 can include first to fourth touch auxiliary lines 410, 420, 430, and 440.

The first touch auxiliary line 410 is configured to improve touch sensitivity (or touch performance) at the first edge portion of the touch panel 200. The first touch auxiliary line 410 is substantially the same as the first touch auxiliary line 410 described above with reference to FIGS. 11 to 17, and thus, repetitive description thereof is omitted.

The second touch auxiliary line 420 is configured to improve touch sensitivity (or touch performance) at the second edge portion of the touch panel 200. The second touch auxiliary line 420 is substantially the same as the second touch auxiliary line 420 described above with reference to FIGS. 11 to 17, and thus, repetitive description thereof is omitted.

The third touch auxiliary line 430 can be configured at the third edge portion of the touch panel 200 to be connected to one end of the first touch auxiliary line 410 and one end of the second touch auxiliary line 420. For example, the third touch auxiliary line 430 can be configured at the third edge portion of the touch panel 200 to be parallel to the first touch sensing electrode TSE1 of each of the first to m^{th} touch sensing lines RX1 to RXm.

The third touch auxiliary line 430 can be configured to form edge capacitance with each of the first to m^{th} touch sensing lines RX1 to RXm. For example, the third touch auxiliary line 430 can form the edge capacitance with the first touch sensing electrode TSE1 of each of the first to m^{th} touch sensing lines RX1 to RXm. For example, the third touch auxiliary line 430 can form the edge capacitance in common with the first touch sensing electrode TSE1 of each of the first to m^{th} touch sensing lines RX1 to RXm. Accordingly, the edge capacitance is formed between each of the first to m^{th} touch sensing lines RX1 to RXm and the third touch auxiliary line 430, and thus, mutual capacitance between each of the first to m^{th} touch sensing lines RX1 to RXm and the first to n^{th} touch driving lines TX1 to TXn can be increased. Therefore, the third touch auxiliary line 430 can improve touch sensitivity (or touch performance) at the third edge portion of the touch panel 200.

The fourth touch auxiliary line 440 can be configured at the fourth edge portion of the touch panel 200 to be connected to the other end of the first touch auxiliary line 410 and the other end of the second touch auxiliary line 420. For example, the fourth touch auxiliary line 440 can be configured at the fourth edge portion of the touch panel 200 to be parallel to the j^{th} touch sensing electrode TSj of each of the first to m^{th} touch sensing lines RX1 to RXm.

The fourth touch auxiliary line 440 can be configured to form the edge capacitance with each of the first to m^{th} touch sensing lines RX1 to RXm. For example, the fourth touch auxiliary line 440 can form the edge capacitance with the j^{th} touch sensing electrode TSEj of each of the first to m^{th} touch sensing lines RX1 to RXm. For example, the fourth touch auxiliary line 440 can form the edge capacitance in common with the j^{th} touch sensing electrode TSEj of each of the first to m^{th} touch sensing lines RX1 to RXm. Accordingly, since the edge capacitance is formed between each of the first to m^{th} touch sensing lines RX1 to RXm and the fourth touch auxiliary line 440, mutual capacitance between each of the first to m^{th} touch sensing lines RX1 to RXm and the first to n^{th} touch driving lines TX1 to TXn can be increased. Therefore, the fourth touch auxiliary line 440 can improve touch sensitivity (or touch performance) at the fourth edge portion of the touch panel 200.

The touch auxiliary line 400 including the first to fourth touch auxiliary lines 410, 420, 430, and 440 can receive an auxiliary driving signal supplied from the touch driving circuit (or the touch driving part). The auxiliary driving signal can be synchronized with the touch driving signal sequentially applied to the first to n^{th} touch driving lines TX1 to TXn. The touch driving circuit (or the touch driving part) is substantially the same as the touch driving circuit (or the touch driving part) described above with reference to FIGS. 14 to 17, except for applying an auxiliary driving signal to the touch auxiliary line 400 including the first to fourth touch auxiliary lines 410, 420, 430, and 440, and thus, repetitive description thereof is omitted. Furthermore, since the auxiliary driving signal is substantially the same as the auxiliary driving signal described above with reference to FIGS. 14 to 17, and thus, repetitive description thereof is omitted.

According to another embodiment of the present disclosure, since the touch auxiliary line 400 is disposed (or configured) in a ring shape along the edge portion of the touch panel 200, touch sensitivity (or touch performance) at the edge portion of the screen can be further improved as the capacitance of each of the first to m^{th} touch sensing lines RX1 to RXm increases (or reinforced), and non-uniformity of touch sensitivity (or touch performance) can be prevented or minimized.

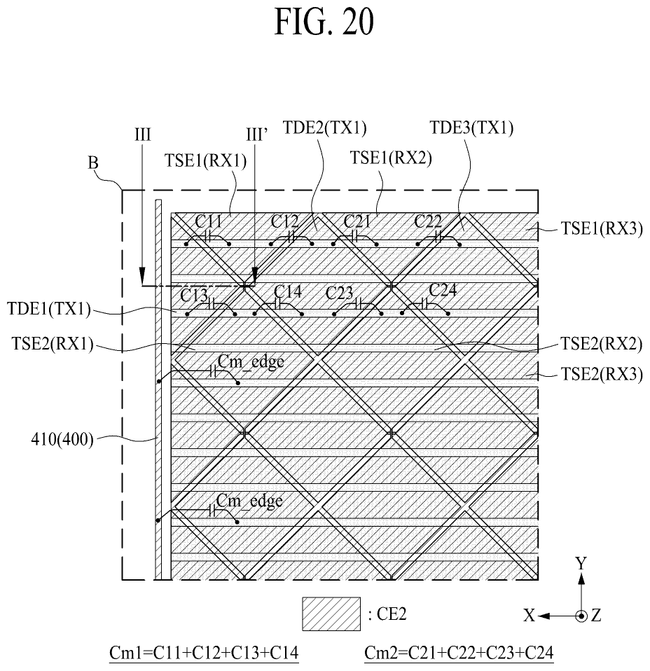

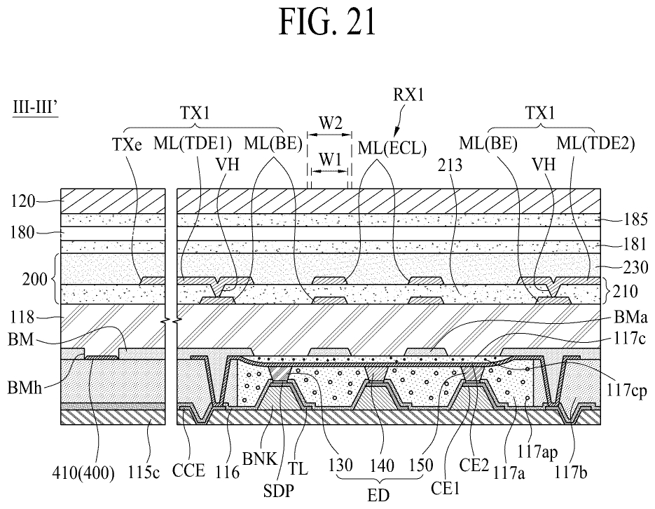

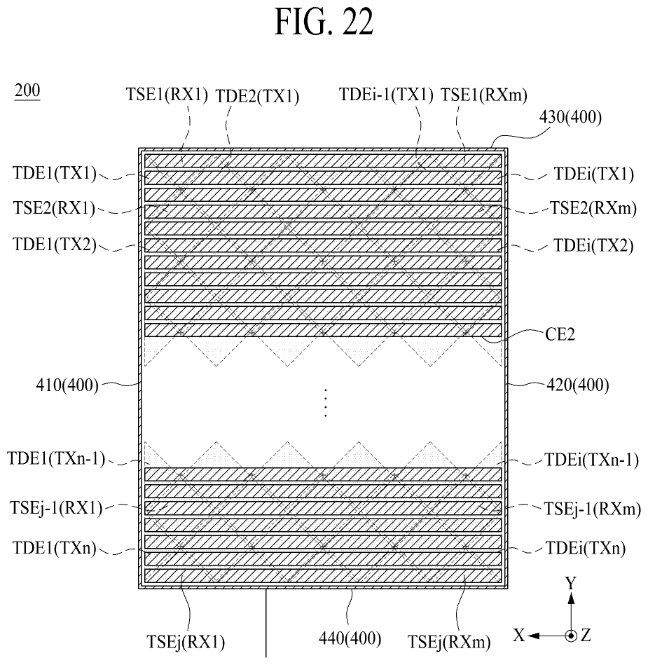

FIG. 19 is a diagram illustrating a second electrode and a touch panel in a display apparatus according to another embodiment of the present disclosure. FIG. 20 is an enlarged view of ‘B’ illustrated in FIG. 19. FIG. 21 is a cross-sectional view taken along line III-III′ illustrated in FIG. 20. For example, FIGS. 19 to 21 illustrate an embodiment implemented by modifying the touch auxiliary line described above with reference to FIGS. 11 to 17. In the following description, therefore, the touch auxiliary line will be only described, and their repetitive descriptions are omitted or will be briefly given. Therefore, descriptions of FIGS. 11 to 17 can be included in descriptions to FIGS. 19 to 21.

Referring to FIGS. 19 to 21, in the display apparatus according to another embodiment of the present disclosure, the touch auxiliary line 400 can be configured to improve touch sensitivity (or touch performance) at an edge portion of a screen. For example, the touch auxiliary line 400 can be disposed (or configured) at the display panel. The touch auxiliary line 400 can be disposed (or configured) under the touch panel 200. The touch auxiliary line 400 can be disposed (or configured) at a metal layer under the touch panel 200.

The touch auxiliary line 400 can be disposed (or configured) to increase a total capacitance of the first and m^{th} touch sensing lines RX1 and RXm which are disposed (or configured) at the edge portion of the screen among the first to m^{th} touch sensing lines RX1 to RXm. The touch auxiliary line 400 can be formed (or configured) at the display panel to be spaced apart from the ends TXe of each of the first and i^{th} touch driving electrodes TDE1 and TDEi configuring (or forming) each of the first to n^{th} touch driving lines TX1 to TXn.

The touch auxiliary line 400 according to an embodiment can be formed of the same material as that of the second electrode (or common electrode) CE2 or can be formed (or configured) on the same layer as that of the second electrode CE2. For example, the touch auxiliary line 400 can be formed of an electrode material (or a metal material) of the second electrode CE2 deposited (or formed) on an edge portion of the display panel. For example, an electrode material (or a metal material) of the second electrode CE2 deposited (or formed) on the edge portion of the display panel can be used as the touch auxiliary line 400 by remaining on the edge portion of the display panel without being patterned (or removed) in a patterning (or removed) process of the second electrode CE2. Accordingly, the touch auxiliary line 400 can be formed (or configured) together with the second electrode CE2.

The touch auxiliary line 400 according to an embodiment can be formed (or configured) over the optical layer 117b to correspond to the edge portion of the display panel. For example, the touch auxiliary line 400 can be disposed (or interposed) between the optical layer 117b and the black matrix BM to correspond to the edge portion of the display panel. The touch auxiliary line 400 can be covered by the black matrix BM, but is not limited thereto. For example, a portion of the black matrix BM at the edge portion of the display panel can further include an opening hole (or an exposure hole) BMh overlapping the touch auxiliary line 400. For example, the opening hole BMh of the black matrix BM can have the same shape as that of the touch auxiliary line 400. A line width of the opening hole of the black matrix BM can be equal to or greater than the line width of the touch auxiliary line 400. The opening hole BMh of the black matrix BM can be covered by the cover layer 118. For example, the cover layer 118 can be filled in the opening hole BMh of the black matrix BM.

The touch auxiliary line 400 according to another embodiment of the present disclosure can include a first touch auxiliary line 410 and a second touch auxiliary line 420.

The first touch auxiliary line 410 can improve touch sensitivity (or touch performance) at the first edge portion of the touch panel 200. The first touch auxiliary line 410 can be formed (or configured) at the first edge portion of the display panel together with the second electrode CE2 using the same material as the second electrode CE2. The first touch auxiliary line 410 can be disposed (or interposed) between the optical layer 117b and the black matrix BM to correspond to the first edge portion of the display panel. The first touch auxiliary line 410 can be configured to form an edge capacitance with the first touch sensing line RX1. For example, the first touch auxiliary line 410 can form the edge capacitance with each of the first to j^{th} touch sensing electrodes TSE1 to TSEj of the first touch sensing line RX1. Except that the first touch auxiliary line 410 is formed (or configured) together with the second electrode CE2, the first touch auxiliary line 410 is substantially the same as the first touch auxiliary line 410 described above with reference to FIGS. 11 to 17, and thus, repetitive description thereof is omitted. The description of the first touch auxiliary line 410 provided above with reference to FIGS. 11 to 17 can be included in the description of the first touch auxiliary line 410 illustrated in FIGS. 19 to 21.

The second touch auxiliary line 420 can improve touch sensitivity (or touch performance) at the second edge portion of the touch panel 200. The second touch auxiliary line 420 can be formed (or configured) at the second edge portion of the display panel together with the second electrode CE2 using the same material as the second electrode CE2. The second touch auxiliary line 420 can be disposed (or interposed) between the optical layer 117b and the black matrix BM to correspond to the second edge portion of the display panel. The second touch auxiliary line 420 can be configured to form an edge capacitance with the m^{th} touch sensing line RXm. For example, the second touch auxiliary line 420 can form the edge capacitance with each of the first to j^{th} touch sensing electrodes TSE1 to TSEj of the m^{th} touch sensing line RXm. Except that the second touch auxiliary line 420 is formed (or configured) together with the second electrode CE2, the second touch auxiliary line 420 is substantially the same as the second touch auxiliary line 420 described above with reference to FIGS. 11 to 17, and thus, repetitive description thereof is omitted. The description of the second touch auxiliary line 420 provided above with reference to FIGS. 11 to 17 can be included in the description of the second touch auxiliary line 420 illustrated in FIGS. 19 to 21.

The display apparatus according to another embodiment of the present disclosure includes the touch auxiliary line 400 formed (or configured) at the edge portion of the display panel together with the second electrode CE2 using the same material as the second electrode CE2, so that as the capacitance of each of the first to m^{th} touch sensing lines RX1 to RXm increases (or is reinforced), touch sensitivity (or touch performance) at the edge portion of the screen can be improved, and non-uniformity of touch sensitivity (or touch performance) can be prevented or minimized.

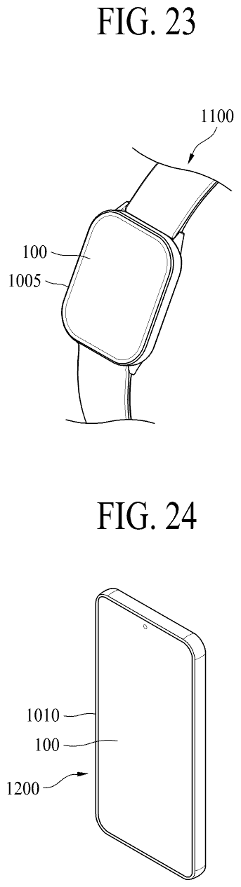

FIG. 22 is a diagram illustrating a touch panel of a display apparatus according to another embodiment of the present disclosure. For example, FIG. 22 illustrates an embodiment implemented by modifying the touch auxiliary line described above with reference to FIGS. 19 to 21. In the following description, therefore, the touch auxiliary line will be only described, and their repetitive descriptions are omitted or will be briefly given. Therefore, descriptions of FIGS. 19 to 21 can be included in descriptions to FIG. 22.

Referring to FIG. 22, in the display apparatus according to another embodiment of the present disclosure, the touch auxiliary line 400 can include first to fourth touch auxiliary lines 410, 420, 430, and 440. For example, the touch auxiliary line 400 can include a ring shape including first to fourth touch auxiliary lines 410, 420, 430, and 440.

Each of the first touch auxiliary line 410 and the second touch auxiliary line 420 is substantially the same as each of the first touch auxiliary line 410 and the second touch auxiliary line 420 described above with reference to FIGS. 19 to 21, and thus, their repetitive descriptions are omitted.

The third touch auxiliary line 430 can be configured to improve touch sensitivity (or touch performance) at the third edge portion of the touch panel 200. The third touch auxiliary line 430 can be configured at the third edge portion of the display panel to be connected to one end of the first touch auxiliary line 410 and one end of the second touch auxiliary line 420. Except that the third touch auxiliary line 430 is formed (or configured) at the third edge portion of the display panel together with the second electrode CE2, the third touch auxiliary line 430 is substantially the same as the first touch auxiliary line 410 described above with reference to FIGS. 19 to 21, and thus, repetitive description thereon is omitted.

The fourth touch auxiliary line 440 can be configured to improve touch sensitivity (or touch performance) at the fourth edge portion of the touch panel 200. The fourth touch auxiliary line 440 can be configured at the fourth edge portion of the display panel to be connected to the other end of the first touch auxiliary line 410 and the other end of the second touch auxiliary line 420. Except that the fourth touch auxiliary line 440 is formed (or configured) in the fourth edge portion of the display panel together with the second electrode CE2, the fourth touch auxiliary line 440 is substantially the same as the first touch auxiliary line 410 described above with reference to FIGS. 19 to 21, and thus, repetitive description thereof is omitted.

The display apparatus according to another embodiment of the present disclosure includes the touch auxiliary line 400 which is formed (or configured) in the ring shape along the edge portion of the display panel together with the second electrode CE2 using the same material as the second electrode CE2, and thus, as the capacitance of each of the first to m^{th} touch sensing lines RX1 to RXm increases (or is reinforced), the touch sensitivity (or touch performance) at the edge portion of the screen can be further improved, and the non-uniformity of touch sensitivity (or touch performance) can be prevented or minimized.

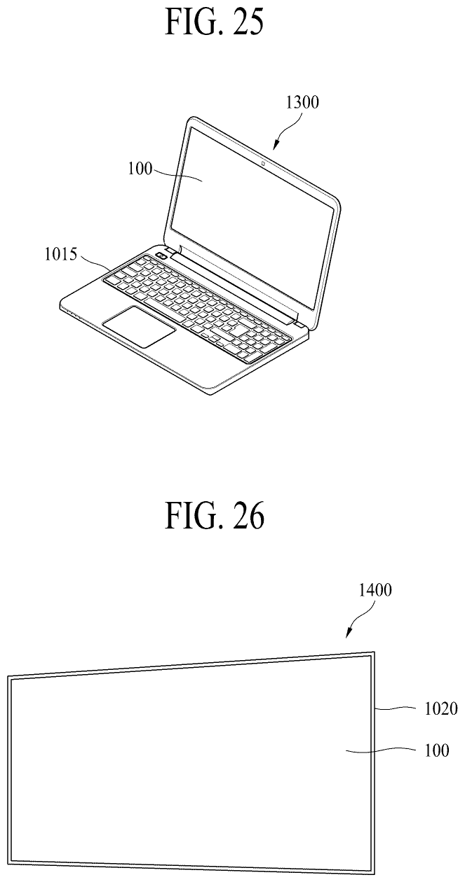

FIGS. 23 to 26 are diagrams illustrating examples of an apparatus to which a display apparatus according to embodiments of the present disclosure is applied.

Referring to FIGS. 23 to 26, the display apparatus according to an embodiments of the present disclosure can be applied to or included in various apparatuses or electronic apparatuses. For example, the various electronic apparatuses can include a wearable device 1100 illustrated in FIG. 23, a mobile device 1200 illustrated in FIG. 24, a notebook 1300 illustrated in FIG. 25, and a monitor or TV 1400 illustrated in FIG. 26, but is not limited thereto.

Each of the wearable device 1100, the mobile device 1200, the notebook 1300, and the monitor or TV 1400 can include a case part 1005, 1010, 1015, and 1020, and the display apparatus 1000 according to the above-described embodiments of the present disclosure. Therefore, descriptions to the display apparatus 1000 are omitted. The description with reference above to FIGS. 1 to 22 can be included in the description of FIGS. 23 to 26.

For example, the display apparatus according to one or more embodiments of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a PMP (a portable multimedia player), a PDA (a personal digital assistant), an MP3 (MPEG Audio Layer 3) player, a mobile medical device, a desktop personal computer, a laptop personal computer, a netbook computer, a workstation, a navigation, a vehicle display apparatus, a theater display apparatus, a television, a wallpaper device, a signage device, a game device, a notebook, a monitor, a camera, a camcorder, or a home appliances, or the like. However, this application is not limited to the listed devices.

It will be apparent to those skilled in the art that various modifications and variations can be made in the present disclosure without departing from the spirit or scope of the disclosures. Thus, it is intended that the present disclosure covers the modifications and variations of this disclosure provided that within the scope of the claims and their equivalents.

What is claimed is:

1. A display apparatus, comprising:
a display panel including a plurality of pixel driving circuits;
a touch panel configured on the display panel; and
a touch auxiliary line configured at the display panel or the touch panel,
wherein the touch panel comprises:
first to n^{th} touch driving lines, where n is a natural number equal to or greater than 4; and
first to m^{th} touch sensing lines configured to form a mutual capacitance with adjacent touch driving lines of the first to n^{th} touch driving lines, where m is a natural number equal to or greater than 4, and
wherein the touch auxiliary line is spaced apart from an end of each of the first to n^{th} touch driving lines and is configured to form the mutual capacitance with at least some of the first to m^{th} touch sensing lines.

2. The display apparatus of claim 1, wherein:
each of the first to n^{th} touch driving lines comprises:
first to ith touch driving electrodes. where i is a natural number equal to or greater than 4; and
a plurality of bridge electrodes configured to connect between the first to ith touch driving electrodes,
in one of the first to n^{th} touch driving lines, each of the first touch driving electrode and the ith touch driving electrode has a size smaller than a size of one of the second to (i−1)th touch driving electrodes, and
the touch auxiliary line is spaced apart from an end of each of the first and ith touch driving electrodes of each of the first to n^{th} touch driving lines.

3. The display apparatus of claim 2, wherein:
in one of the first to n^{th} touch driving lines, each of the second to (i−1)^{th} touch driving electrodes has a rectangular or a rhombus shape,
in one of the first to n^{th} touch driving lines, each of the first touch driving electrode and the ith touch driving electrode has the same shape as or a different from one of the second to (i−1)^{th} touch driving electrodes, and
the touch auxiliary line is configured to be parallel to the first to m^{th} touch sensing lines.

4. The display apparatus of claim 3, wherein the touch auxiliary line comprises:
a first touch auxiliary line configured to be adjacent to the first touch driving electrode of each of the first to n^{th} touch driving lines; and
a second touch auxiliary line configured to be adjacent to the ith touch driving electrode of each of the first to n^{th} touch driving lines.

5. The display apparatus of claim 2, wherein the touch auxiliary line is spaced apart from an end of each of the first to n^{th} touch driving lines and from an end of each of the first to m^{th} touch sensing lines, and is configured to form the mutual capacitance with each of the first to m^{th} touch sensing lines.

6. The display apparatus of claim 2, wherein:
each of the first to m^{th} touch sensing lines comprises:
first to j^{th} touch sensing electrodes, where j is a natural number equal to or greater than 4; and
a plurality of electrode connection lines configured to connect between the first to j^{th} touch sensing electrodes,
in one of the first to m^{th} touch sensing lines, each of the first touch sensing electrode and the j^{th} touch sensing electrode has a size smaller than a size of one of the second to (j−1)^{th} touch sensing electrodes, and
the touch auxiliary line is spaced apart from an end of each of the first and j^{th} touch sensing electrodes of each of the first to m^{th} touch sensing lines.

7. The display apparatus of claim 6, wherein:
in one of the first to m^{th} touch sensing lines, each of the second to (j−1)^{th} touch sensing electrodes has a rectangular or a rhombus shape,
in one of the first to m^{th} touch sensing lines, each of the first touch sensing electrode and the j^{th} touch sensing electrode has the same shape as or a different from one of the second to (j−1)^{th} touch sensing electrodes, and
the touch auxiliary line includes a ring shape overlapping with an edge portion of the touch panel.

8. The display apparatus of claim 6, wherein:
the touch panel comprises:
a first touch electrode layer;
a touch insulating layer covering the first touch electrode layer; and
a second touch electrode layer on the touch insulating layer,
the first to i^{th} touch driving electrodes are configured at any one of the first touch electrode layer and the second touch electrode layer,
the plurality of bridge electrodes are configured on a layer different from that of the first to i^{th} touch driving electrodes of the first touch electrode layer and the second touch electrode layer,
each of the plurality of bridge electrodes is configured to be electrically connected to two adjacent touch driving electrodes of the first to i^{th} touch driving electrodes through a via hole provided at the touch insulating layer, and
the first to j^{th} touch sensing electrodes and the plurality of electrode connection lines are configured on a same layer as the first to i^{th} touch driving electrodes.

9. The display apparatus of claim 2, wherein the touch auxiliary line is configured on the same layer as the first to m^{th} touch sensing lines or on a same layer as the plurality of bridge electrodes.

10. The display apparatus of claim 1, further comprising a touch driving circuit electrically connected to the first to n^{th} touch driving lines, the first to m^{th} touch sensing lines, and the touch auxiliary line,
wherein the touch driving circuit is configured to supply a touch driving signal to each of the first to n^{th} touch driving lines and to supply an auxiliary driving signal synchronized with the touch driving signal to the touch auxiliary line.

11. The display apparatus of claim 10, wherein each of the touch driving signal and the auxiliary driving signal includes one or more pulse signals having a same phase, a same pulse width, and a same voltage level.

12. The display apparatus of claim 10, wherein:
each of the touch driving signal and the auxiliary driving signal includes one or more pulse signals having a same phase and a same pulse width, and
the one or more pulse signals of the touch driving signal and the one or more pulse signals of the auxiliary driving signal have different voltage levels from each other.

13. The display apparatus of claim 1, wherein the display panel comprises:
a substrate including a display area and a non-display area;
the plurality of pixel driving circuits in the display area on the substrate;
an insulating layer covering the plurality of pixel driving circuits;
a plurality of light emitting devices electrically connected to the plurality of pixel driving circuits;
a common electrode electrically connected to the plurality of light emitting devices; and
a cover layer covering the common electrode.

14. The display apparatus of claim 13, wherein the touch auxiliary line is configured on a same layer as the first to m^{th} touch sensing lines or is configured to include a same material as the common electrode.

15. The display apparatus of claim 13, wherein the touch panel comprises:
a touch electrode layer configured on the cover layer of the display panel and including the first to n^{th} touch driving lines and the first to m^{th} touch sensing lines; and
a passivation layer covering the touch electrode layer.

16. The display apparatus of claim 15, wherein the touch auxiliary line is configured on a same layer as the first to m^{th} touch sensing lines or on a same layer as the common electrode.

17. The display apparatus of claim 13, wherein:
the display panel further comprises a black matrix having a plurality of openings overlapping the plurality of light emitting devices,
each of the first to n^{th} touch driving lines and each of the first to m^{th} touch sensing lines includes a mesh structure having mesh lines, and
the mesh lines overlap the black matrix and have a line width smaller than a line width of the black matrix.

18. The display apparatus of claim 13, wherein:
the display panel further comprises:
a plurality of banks in the insulating layer;
a plurality of connection electrodes in the plurality of banks and electrically connected to a corresponding pixel driving circuit of the plurality of pixel driving circuits; and
a plurality of bonding pads on the plurality of connection electrodes, and each of the plurality of light emitting devices comprises:
a first electrode electrically connected to a corresponding bonding pad of the plurality of bonding pads; and
a second electrode electrically connected to the common electrode.

19. The display apparatus of claim 18, wherein the display panel further comprises an optical layer configured on the insulating layer so as to surround lateral surfaces of at least one of the plurality of light emitting devices and lateral surfaces of at least one of the plurality of banks.

20. The display apparatus of claim 19, wherein the optical layer comprises:
a first optical layer surrounding side portions of at least one of the plurality of light emitting devices and the plurality of banks between the common electrode and the insulating layer;
a second optical layer surrounding side portions of the first optical layer; and
a third optical layer disposed on the common electrode so as to overlap the plurality of light emitting devices and the first optical layer.
